(19) United States
(12) Patent Application Publication
(10) Pub. No.: US 2025/0220885 A1
(43) Pub. Date: Jul. 3, 2025

(54) SEMICONDUCTOR DEVICES

(71) Applicant: Samsung Electronics Co., Ltd., Suwon-si (KR)

(72) Inventors: Chaeseok Kwak, Suwon-si (KR); Youngkwan Park, Suwon-si (KR); Deokhwan Choi, Suwon-si (KR)

(21) Appl. No.: 18/973,269

(22) Filed: Dec. 9, 2024

(30) Foreign Application Priority Data
Dec. 29, 2023 (KR) 10-2023-0197695

(51) Int. Cl. H10B 12/00

(52) U.S. Cl. CPC H10B 12/33; H10B 12/036; H10B 12/05; H10B 12/50

(57) ABSTRACT

A semiconductor device includes a peripheral circuit, a capacitor structure on the peripheral circuit and including a plate electrode and a vertical structure extending on the plate electrode in a vertical direction, the vertical structure including a first electrode, a second electrode, and a capacitor dielectric layer between the first and second electrodes, a cell transistor electrically connected to the capacitor structure, a first cell plug between, in the vertical direction, the plate electrode and the peripheral circuit and adjacent and electrically connected to a bottom surface of the plate electrode, and a second cell plug between, in the vertical direction, the cell transistor and the peripheral circuit, the first cell plug including a first end portion adjacent the peripheral circuit and a second end portion opposite to the first end portion, a width of the second end portion being greater than a width of the first end portion.

### CROSS-REFERENCE TO RELATED APPLICATIONS

This application is based on and claims priority under 35 U.S.C. §119 to Korean Patent Application No. 10-2023-0197695, filed on Dec. 29, 2023, in the Korean Intellectual Property Office, the disclosure of which is incorporated by reference herein in its entirety.

### BACKGROUND OF THE INVENTION

The inventive concept relates to a semiconductor device, and more particularly, to a semiconductor device including a vertical channel transistor.

As semiconductor devices down-scale, the size of dynamic random-access memory (DRAM) devices is decreasing. In a DRAM device with a 1T-1C structure in which one transistor is connected to one capacitor, a leakage current through a channel area may increase gradually along with the miniaturization of the DRAM device. To reduce such leakage current, a vertical channel transistor including an oxide semiconductor material as a channel layer has been suggested.

### SUMMARY OF THE INVENTION

The inventive concept provides a semiconductor device with excellent electrical performance.

According to an aspect of the inventive concept, there is provided a semiconductor device including a peripheral circuit on a substrate, a capacitor structure on the peripheral circuit and including a plate electrode and a vertical structure extending on the plate electrode in a vertical direction perpendicular to an upper surface of the substrate, wherein the vertical structure includes a first electrode, a second electrode, and a capacitor dielectric layer between the first electrode and the second electrode, a cell transistor at a higher vertical level than the capacitor structure and electrically connected to the capacitor structure, a first cell plug between, in the vertical direction, the plate electrode and the peripheral circuit and adjacent and electrically connected to a bottom surface of the plate electrode, and a second cell plug between, in the vertical direction, the cell transistor and the peripheral circuit, wherein the first cell plug includes a first end portion adjacent the peripheral circuit, and a second end portion opposite to the first end portion, and a width of the second end portion is greater than a width of the first end portion.

According to another aspect of the inventive concept, there is provided a semiconductor device including a peripheral circuit on a substrate, a capacitor structure on the peripheral circuit and including a plate electrode and a plurality of vertical structures extending on the plate electrode in a vertical direction perpendicular to an upper surface of the substrate, wherein each of the plurality of vertical structures includes a first electrode, a second electrode, and a capacitor dielectric layer between the first electrode and the second electrode, a mold insulating layer on the plate electrode and including a plurality of openings extending in the vertical direction, wherein the plurality of vertical structures are in the plurality of openings, respectively, an active semiconductor layer on the mold insulating layer and electrically connected to the second electrode, a word line on a sidewall of the active semiconductor layer, a bit line on an upper surface of the active semiconductor layer, a first cell plug between the plate electrode and the peripheral circuit in the vertical direction and adjacent and electrically connected to a bottom surface of the plate electrode, and a second cell plug extending between the word line and the peripheral circuit in the vertical direction and electrically connecting the word line to the peripheral circuit.

According to another aspect of the inventive concept, there is provided a semiconductor device including a peripheral circuit on a substrate, a capacitor structure on the peripheral circuit and including a plate electrode and a plurality of vertical structures extending on the plate electrode in a vertical direction perpendicular to an upper surface of the substrate, wherein each of the plurality of vertical structures includes a first electrode electrically connected to the plate electrode and extending in the vertical direction, a second electrode on a sidewall of the first electrode, and a capacitor dielectric layer between the first electrode and the second electrode, a mold insulating layer on the plate electrode and surrounding sidewalls of the plurality of vertical structures, an active semiconductor layer at a higher vertical level than the capacitor structure, extending in the vertical direction, and including a first end portion and a second end portion, wherein the first end portion is adjacent and electrically connected to the second electrode, a word line on a sidewall of the active semiconductor layer, a bit line adjacent and electrically connected to the second end portion of the active semiconductor layer, a wire layer at a higher vertical level than the bit line, and a first cell plug between the plate electrode and the peripheral circuit in the vertical direction and adjacent and electrically connected to a bottom surface of the plate electrode, a second cell plug extending between the word line and the peripheral circuit in the vertical direction and electrically connecting the word line to the peripheral circuit, a third cell plug extending between the bit line and the peripheral circuit in the vertical direction and electrically connecting the bit line to the peripheral circuit, and a peripheral plug extending between the wire layer and the peripheral circuit in the vertical direction and electrically connecting the wire layer to the peripheral circuit.

### BRIEF DESCRIPTION OF THE DRAWINGS

Embodiments of the inventive concept will be more clearly understood from the following detailed description taken in conjunction with the accompanying drawings in which:

FIG. 1 illustrates a perspective view of a semiconductor device according to embodiments;

FIG. 2 illustrates an enlarged layout of a cell array area of FIG. 1;

FIG. 3 is a cross-sectional view of the semiconductor device taken along a line A1-A1′ of FIG. 2;

FIG. 4 is a cross-sectional view of the semiconductor device taken along a line A2-A2′ of FIG. 2;

FIG. 5 is an enlarged view illustrating a region CX1 of FIG. 3;

FIG. 6 is an enlarged view illustrating a region CX2 of FIG. 3;

FIGS. 7 and 8 are cross-sectional views of a semiconductor device according to embodiments;

FIG. 9 is an enlarged view illustrating a region CX1 of FIG. 7;

FIG. 10 is an enlarged view illustrating a region CX2 of FIG. 7;

FIG. 11 is a cross-sectional view of a semiconductor device according to embodiments;

FIGS. 12 to 15, 16A, 16B, 17A, 17B, 18, 19A, 19B, 20A, 20B, 21A, and 21B schematically illustrate a method of manufacturing a semiconductor device, according to embodiments; and

FIGS. 22, 23, 24A, 24B, 25A, and 25B schematically illustrate a method of manufacturing a semiconductor device, according to embodiments.

### DETAILED DESCRIPTION

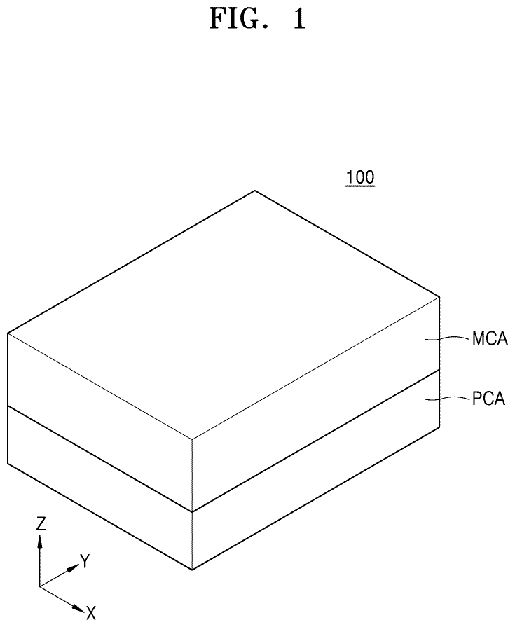

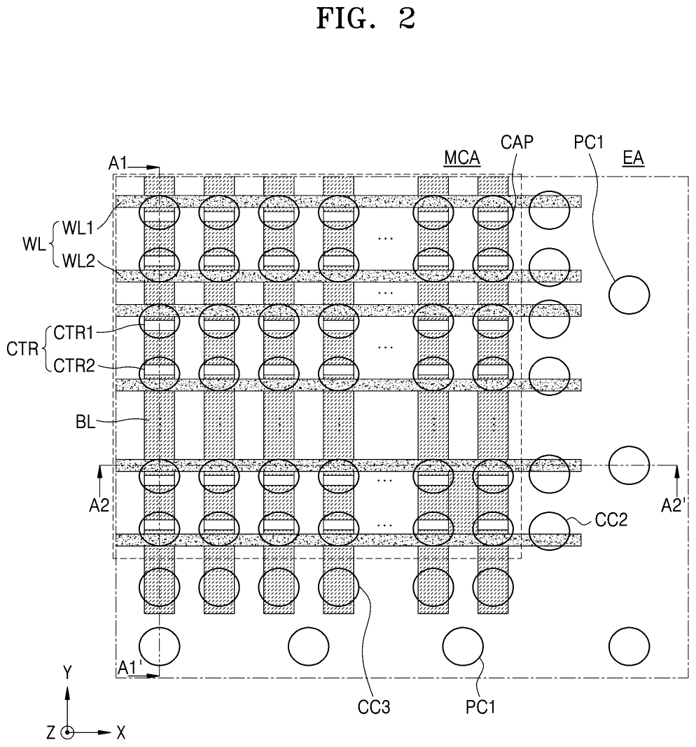

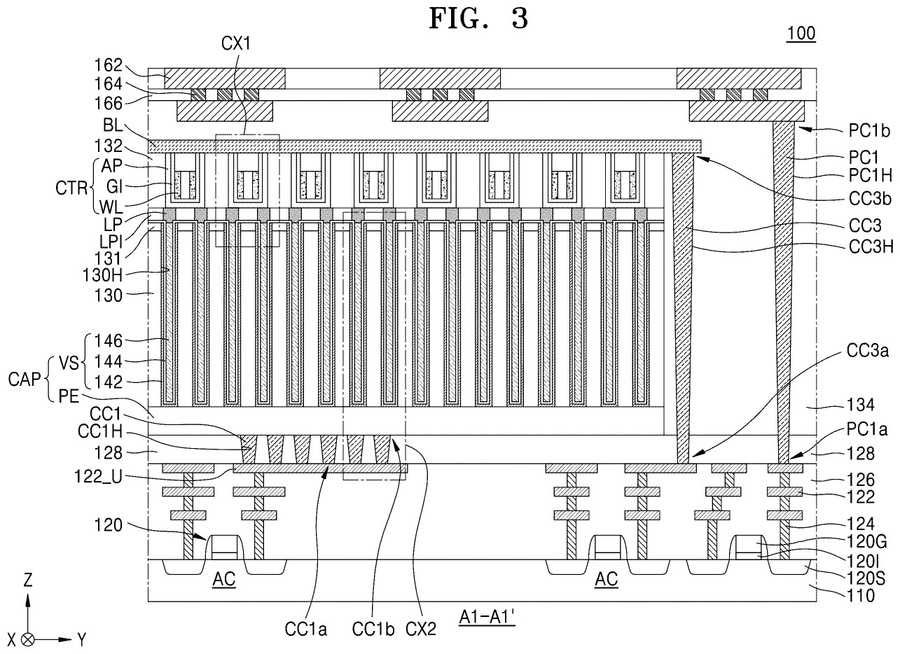

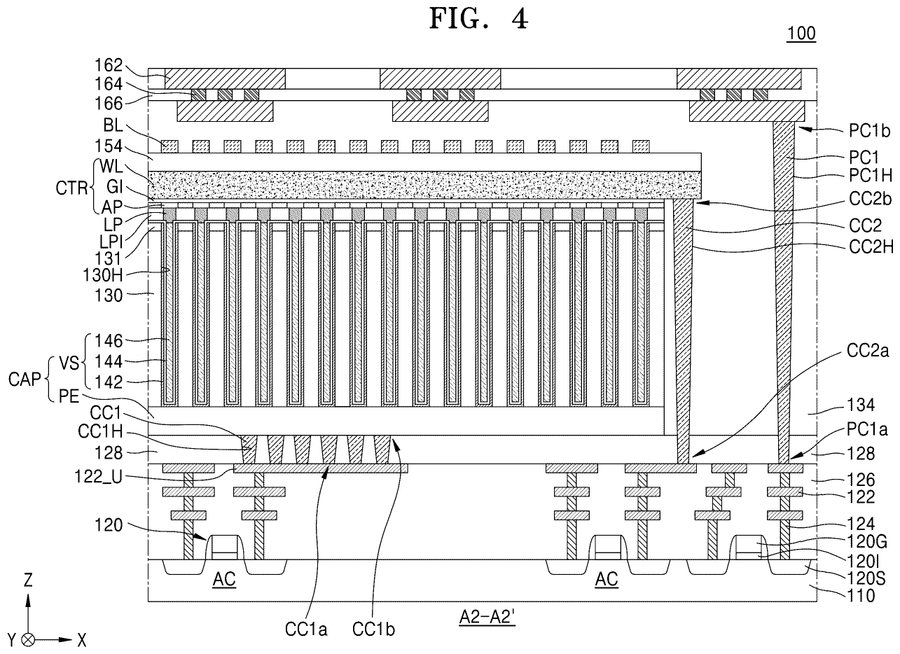

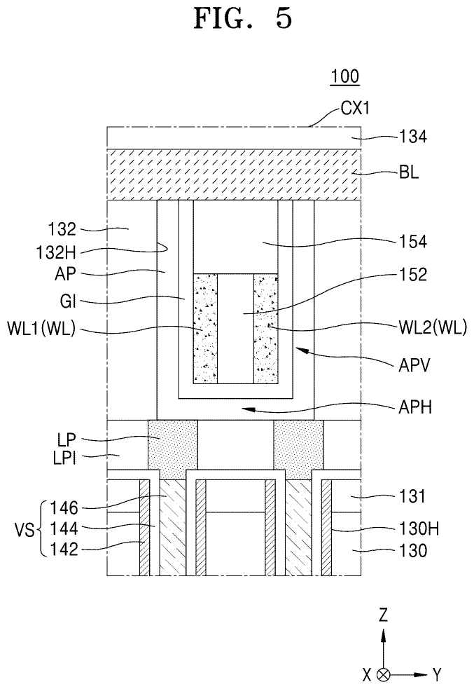

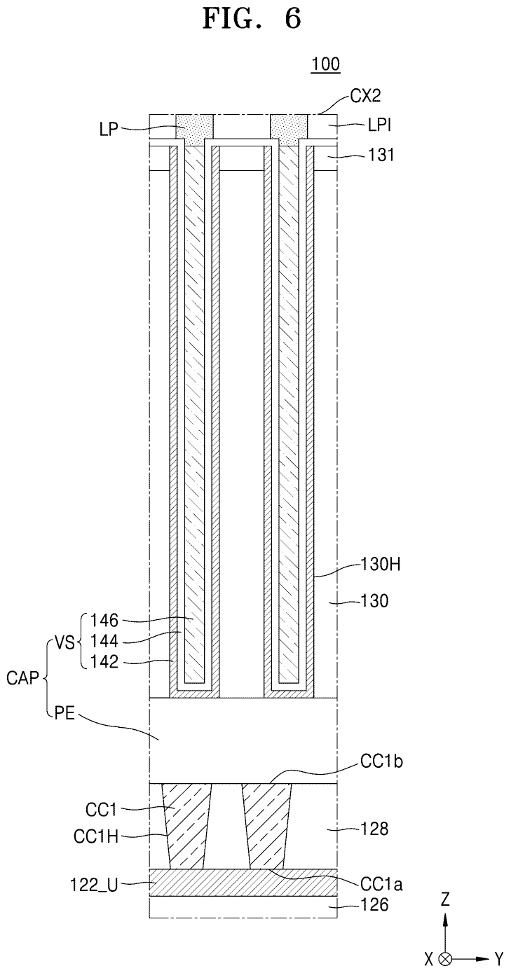

FIG. 1 illustrates a perspective view of a semiconductor device 100 according to embodiments. FIG. 2 illustrates an enlarged layout of a cell array area MCA of FIG. 1. FIG. 3 is a cross-sectional view of the semiconductor device 100 taken along a line A1-A1′ of FIG. 2. FIG. 4 is a cross-sectional view of the semiconductor device 100 taken along a line A2-A2′ of FIG. 2. FIG. 5 is an enlarged view illustrating a region CX1 of FIG. 3. FIG. 6 is an enlarged view illustrating a region CX2 of FIG. 3.

Referring to FIGS. 1 to 6, the semiconductor device 100 may include a peripheral circuit area PCA and a cell array area MCA at a higher vertical level than the peripheral circuit area PCA.

In some embodiments, the cell array area MCA may be a memory cell area of a dynamic random-access memory (DRAM) device, and the peripheral circuit area PCA may be a core area or a peripheral circuit area of the DRAM device. For example, the peripheral circuit area PCA may include a peripheral circuit transistor 120 configured to transmit signals and/or power to a memory cell array included in the cell array area MCA. In embodiments, the peripheral circuit transistor 120 may configure various circuits, such as a command decoder, a control logic, an address buffer, a row decoder, a column decoder, a sense amplifier, and a data input/output circuit.

As illustrated in FIG. 2, in the cell array area MCA, a plurality of word lines WL extending in a first horizontal direction X and a plurality of bit lines BL extending in a second horizontal direction Y may be arranged. At cross points where the plurality of word lines WL cross the plurality of bit lines BL, a plurality of cell transistors CTR may be arranged. A plurality of vertical structures VS may be arranged on (e.g., under) the cell transistors CTR, respectively.

The word lines WL may include first word lines WL1 and second word lines WL2 that are alternately arranged in the second horizontal direction Y, and the cell transistors CTR may include first cell transistors CTR1 and second cell transistors CTR2 that are alternately arranged in the second horizontal direction Y. The first cell transistor CTR1 may be arranged adjacent to the first word line WL1, and the second cell transistor CTR2 may be arranged adjacent to the second word line WL2.

The first cell transistor CTR1 and the second cell transistor CTR2 may have a mirror symmetry structure with respect to each other. For example, the first cell transistor CTR1 and the second cell transistor CTR2 may have the mirror symmetry structure with respect to a center line between the first cell transistor CTR1 and the second cell transistor CTR2, the center line extending in the first horizontal direction X.

In embodiments, widths of the word lines WL may be 1F, pitches (that is, a sum of a width and a gap) of the word lines WL may be 2F, widths of the bit lines BL may be 1F, pitches (that is, a sum of a width and a gap) of the bit lines BL may be 2F, and a unit area for forming one cell transistor CTR may be 4F². Therefore, because the cell transistor CTR may be of a crosspoint type that requires a relatively small unit area, it may be advantageous for improving the integration of the semiconductor device 100.

Edge areas EA may be located near the cell array area MCA. The edge area EA may be an area where an electrical connection member for the word line WL and/or an electrical connection member for the bit line BL may be arranged and may be an area including an electrical connection member for enabling an electrical connection between the cell array area MCA and the peripheral circuit area PCA.

A substrate 110 may include silicon such as single crystalline silicon, polycrystalline silicon, or amorphous silicon. In other embodiments, the substrate 110 may include at least one selected from among germanium (Ge), silicon-germanium (SiGe), silicon carbide (SiC), gallium arsenide (GaAs), indium arsenide (InAs), and indium phosphide (InP). In some embodiments, the substrate 110 may include a conductive area, for example, a well doped with impurities or a structure doped with impurities.

In the peripheral circuit area PCA, an active area AC may be defined in a substrate 110, and the peripheral circuit transistor 120 may be arranged in the active area AC of the substrate 110. The peripheral circuit transistor 120 may include a gate electrode 120G, a gate insulating layer 120I, and a source/drain area 120S, and for example, the peripheral circuit transistor 120 may be electrically connected to the bit line BL or the word line WL through a peripheral circuit line 122 and a peripheral circuit contact 124.

A peripheral circuit insulating layer 126 may cover the peripheral circuit transistor 120, the peripheral circuit line 122, and the peripheral circuit contact 124 on the substrate 110. The peripheral circuit insulating layer 126 may include an oxide layer, a nitride layer, a low-k dielectric layer, or a combination thereof and may have a stack structure including a plurality of insulating layers.

An isolation insulating layer 128 may be arranged on the peripheral circuit insulating layer 126, and a capacitor structure CAP may be arranged on the isolation insulating layer 128. The capacitor structure CAP may have a capacitor configuration of a metal-insulator-metal type. The capacitor structure CAP may include a plate electrode PE and a plurality of vertical structures VS on the plate electrode PE.

In embodiments, the plate electrode PE may have a planar shape extending in the first horizontal direction X and the second horizontal direction Y. In embodiments, the plate electrode PE may include Si, SiGe, tungsten (W), tungsten nitride (WN), titanium (Ti), titanium nitride (TiN), and a combination thereof.

A first cell plug CC1 may be arranged between the plate electrode PE and the peripheral circuit line 122. An upper surface of the first cell plug CC1 may contact (and thus be adjacent and electrically connected to) a bottom surface of the plate electrode PE, and a bottom surface of the first cell plug CC1 may contact an upper surface of an uppermost peripheral circuit line 122_U. The first cell plug CC1 may electrically connect the plate electrode PE to the peripheral circuit transistor 120 through the peripheral circuit line 122.

In embodiments, the first cell plug CC1 may be located in a first cell plug hole CC1H penetrating the isolation insulating layer 128. The first cell plug hole CC1H may be formed through a process of removing a portion of the isolation insulating layer 128 from the upper surface of the isolation insulating layer 128, and in embodiments, the first cell plug hole CC1H may have inclined sidewalls such that an upper width of the first cell plug hole CC1H is greater than a bottom width of the first cell plug hole CC1H.

The first cell plug CC1 may include a first end portion CC1a (e.g., the first end portion CC1a in contact with the upper surface of the uppermost peripheral circuit line 122_U) arranged to be close to (i.e., adjacent) the peripheral circuit transistor 120 and a second end portion CC1b opposite to the first end portion CC1a. The width of the second end portion CC1b of the first cell plug CC1 may be greater than the width of the first end portion CC1a of the first cell plug CC1. The first cell plug CC1 may thus be tapered toward a peripheral circuit of the peripheral circuit area PCA.

The vertical structures VS may extend on the plate electrode PE in the vertical direction Z. For example, each vertical structure VS may include a first electrode 142, a capacitor dielectric layer 144, and a second electrode 146. Each vertical structure VS may have a relatively high aspect ratio, and the height of the vertical structure VS in the vertical direction Z may be greater than the width of the vertical structure VS in the first horizontal direction X.

The vertical structures VS may be surrounded by a capacitor mold insulating layer 130. For example, the capacitor mold insulating layer 130 may be arranged on the plate electrode PE and include a plurality of openings 130H penetrating the capacitor mold insulating layer 130 and extending in the vertical direction Z. The vertical structures VS may be respectively located in the openings 130H of the capacitor mold insulating layer 130. Accordingly, the vertical structures VS may be arranged to extend in the vertical direction Z by penetrating the capacitor mold insulating layer 130. The bottom surface of the capacitor mold insulating layer 130 may be in contact with the upper surface of the plate electrode PE.

The first electrode 142 may be arranged on the inner wall of each opening 130H. The first electrode 142 may have a cylindrical shape with a closed bottom and extend in the vertical direction Z in each opening 130H. The bottom surface of the first electrode 142 may be in contact with the upper surface of the plate electrode PE.

The capacitor dielectric layer 144 may be arranged on the inner wall of each opening 130H, for example, the inner sidewall of the first electrode 142.

The second electrode 146 may be in (e.g., may fill) the interior (e.g., middle portion) of each opening 130H such that the capacitor dielectric layer 144 is arranged between the second electrode 146 and the first electrode 142. The bottom surface and the sidewall of the second electrode 146 may be surrounded by the capacitor dielectric layer 144, and the second electrode 146 may have a pillar (e.g., rectangular or cylindrical) shape extending in the vertical direction Z. In a horizontal cross-section (i.e., an X-Y plane), the first electrode 142 may be ring-shaped and the second electrode 146 may have a circular shape. The ring-shaped horizontal cross-section of the first electrode 142 may surround (e.g., enclose) the circular horizontal cross-section of the second electrode 146.

Selectively, an etch stop layer 131 may be arranged on the upper surface of the capacitor mold insulating layer 130, and the etch stop layer 131 may surround the upper portion of the side wall of each vertical structure VS. In embodiments, the capacitor dielectric layer 144 may extend from the inner wall of each opening 130H to the upper surface of the capacitor mold insulating layer 130. As shown in FIG. 5, the etch stop layer 131 may be arranged on the upper surface of the capacitor mold insulating layer 130, and a portion of the capacitor dielectric layer 144 may be arranged on the upper surface of the etch stop layer 131.

In embodiments, the first electrode 142 may include Ti, TiN, tantalum (Ta), tantalum nitride (TaN), W, WN, titanium silicon nitride (TiSiN), tungsten silicon nitride (WSiN), polysilicon, SiGe, or a combination thereof. In embodiments, the second electrode 146 may include Ti, TiN, Ta, TaN, W, WN, TiSiN, WSiN, polysilicon, or a combination thereof. In embodiments, the capacitor dielectric layer 144 may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanium oxide (SrTiO), yttrium oxide (YO), aluminum oxide (AlO), and lead scandium tantalum oxide (PbScTaO).

In embodiments, the openings 130H with bottom potions, which expose the upper surface of the plate electrode PE, may be formed by penetrating the capacitor mold insulating layer 130, and the vertical structures VS may be formed by sequentially forming the first electrodes 142, the capacitor dielectric layers 144, and the second electrodes 146 in the openings 130H. During the etching process of removing a portion of the capacitor mold insulating layer 130, an electrical path to the substrate 110 may be provided to the plate electrode PE through the first cell plug CC1 adjacent and electrically connected to (e.g., in contact with) the bottom surface of the plate electrode PE, and electrical damage to the plate electrode PE, for example, arc discharge, which may occur due to collisions of plasma or ions used during the etching process, may be prevented from occurring.

A plurality of landing pads LP may be arranged on the vertical structures VS, respectively. Each landing pad LP may include Ti, TiN, Ta, TaN, W, WN, TiSiN, WSiN, polysilicon, or a combination thereof. A landing pad isolation insulating layer LPI surrounding the sidewalls of the landing pads LP may be arranged on the capacitor mold insulating layer 130.

A channel mold insulating layer 132 may be arranged on the landing pads LP and the landing pad isolation insulating layer LPI and include a plurality of mold openings 132H extending in the first horizontal direction X. The cell transistor CTR may be arranged in each mold opening 132H.

In embodiments, the cell transistor CTR may include an active semiconductor layer AP, a gate insulating layer GI, and a word line WL which are arranged in each mold opening 132H.

In embodiments, the active semiconductor layer AP may have a U-shaped vertical cross-section in each mold opening 132H. The active semiconductor layer AP may include a vertical extension (i.e., a vertical portion) APV extending in the vertical direction Z, and a horizontal extension (i.e., a horizontal portion) APH integrally connected to the bottom portion of the vertical extension APV and extending in the second horizontal direction Y. For example, the vertical extension APV may be arranged on opposite (e.g., both) sidewalls of each mold opening 132H, and the horizontal extension APH may be arranged on the bottom portion of each mold opening 132H. The horizontal extension APH may be arranged to vertically overlap two landing pads LP that are arranged in parallel with each other in the second horizontal direction Y.

In embodiments, the active semiconductor layer AP may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnxONz), magnesium zinc oxide (MgₓZn_{y}O), zirconium indium zinc oxide (ZrₓIn_{y}Zn_{z}O), hafnium indium zinc Oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), and zirconium zinc tin oxide (ZrₓZn_{y}Sn_{z}O).

In embodiments, the active semiconductor layer AP may include a first end portion connected to (e.g., contacting and electrically connected to) the landing pad LP and a second end portion opposite to the first end portion, and the first end portion may refer to the horizontal extension APH and the second end portion may refer to an upper portion of the vertical extension APV. In embodiments, the first end portion and the second end portion of the active semiconductor layer AP may be further doped with impurity ions, and regions doped with impurity ions may function as a source contact and a drain contact, respectively.

The gate insulating layer GI may be arranged on the sidewall of the vertical extension APV and the upper surface of the horizontal extension APH of the active semiconductor layer AP.

In embodiments, the gate insulating layer GI may include at least one selected from high-k dielectric materials with higher dielectric constants than silicon oxide, and ferroelectric materials. In embodiments, the gate insulating layer GI may include at least one material selected from among HfO, HfSiO, HfON, HfSiON, LaO, LaAIO, ZrO, ZrSiO, ZrON, ZrSiON, TaO, TiO, BaSrTiO, BaTiO, PbZrTiO, SrTaBiO, BiFeO, SrTiO, YO, AIO, and PbScTaO.

The word line WL may be arranged in each mold opening 132H of the channel mold insulating layer 132. The word line WL may be arranged on the sidewall of the gate insulating layer GI. In embodiments, the word line WL may include Ti, TiN, Ta, TaN, Mo, Ru, W, WN, TiSiN, WSiN, polysilicon, or a combination thereof. For example, in one mold opening 132H, two word lines WL may be spaced apart from each other and extend in the first horizontal direction X. For example, a first word line WL1 may be arranged on a first sidewall of the mold opening 132H, and a second word line WL2 may be spaced apart from the first word line WL1 on a second sidewall of the mold opening 132H.

In embodiments, within a single mold opening 132H, a first buried insulating layer 152 may be arranged between two word lines WL in one mold opening 132H, and a second buried insulating layer 154 may be arranged on the two word lines WL and the first buried insulating layer 152.

The bit line BL extending in the second horizontal direction Y may be arranged on the cell transistor CTR. The bit line BL may be arranged at a higher vertical level than the capacitor structure CAP with respect to the upper surface of the substrate 110. In embodiments, the bit line BL may be arranged on the second end portion (e.g., the upper side of the vertical extension APV) of the active semiconductor layer AP.

In embodiments, the bit line BL may include Ti, TiN, Ta, TaN, Mo, Ru, W, WN, Co, Ni, TiSi, TiSiN, WSi, WSIN, TaSi, TaSiN, RuTiN, CoSi, NiSi, polysilicon, or a combination thereof.

In embodiments, a shielding structure extending in the second horizontal direction Y may be additionally arranged between the bit lines BL. The shielding structure may include a conductive material such as metal. In embodiments, the shielding structure may include a conductive material and have an air gap or a void therein.

In the edge area EA, the buried insulating layer 134 may cover the capacitor structure CAP and the cell transistor CTR on the isolation insulating layer 128. The buried insulating layer 134 may have a height that is sufficient to cover the capacitor structure CAP, the cell transistor CTR, and the bit lines BL. In embodiments, the buried insulating layer 134 may include an oxide layer, a nitride layer, a low-k dielectric layer, or a combination thereof. In embodiments, the buried insulating layer 134 may include a stack structure including a plurality of insulating layers.

In embodiments, a shielding structure extending in the second horizontal direction Y may be additionally arranged between the bit lines BL. The shielding structure may include a conductive material such as metal. In embodiments, the shielding structure may include a conductive material and have an air gap or a void therein. Alternatively, in other embodiments, air gaps may be defined in the buried insulating layer 134 instead of the shielding structure.

As shown in FIGS. 2 and 4, in the edge area EA, a second cell plug CC2 may be arranged between the cell transistor CTR and the peripheral circuit line 122. For example, an upper surface of the second cell plug CC2 may contact the bottom surface of the word line WL, and a bottom surface of the second cell plug CC2 may contact the upper surface of the uppermost peripheral circuit line 122_U. The second cell plug CC2 may electrically connect the word line WL to the peripheral circuit transistor 120 through the peripheral circuit line 122.

In embodiments, the second cell plug CC2 may be arranged in a second cell plug hole CC2H penetrating the isolation insulating layer 128 and the buried insulating layer 134. The second cell plug hole CC2H may be formed through the process of removing a portion of the buried insulating layer 134 and a portion of the isolation insulating layer 128 from the upper surface of the buried insulating layer 134, and in embodiments, the second cell plug hole CC2H may have inclined sidewalls such that an upper width of the second cell plug hole CC2H is greater than a bottom width thereof.

The second cell plug CC2 may include a first end portion CC2a (e.g., the first end portion CC2a in contact with the upper surface of the uppermost peripheral circuit line 122_U) arranged to be close to (i.e., adjacent) the peripheral circuit transistor 120 and a second end portion CC2b opposite to the first end portion CC2a. The width of the second end portion CC2b of the second cell plug CC2 may be greater than the width of the first end portion CC2a of the second cell plug CC2.

In embodiments, as the capacitor structure CAP is arranged between the cell transistor CTR and the peripheral circuit transistor 120, the height of the second cell plug CC2 in the vertical direction Z may be greater than the height of the capacitor structure CAP in the vertical direction Z (e.g., the height of the vertical structure VS in the vertical direction Z). For example, an upper surface of the second cell plug CC2 may be at a higher vertical level than an upper surface of the vertical structure VS. Moreover, the second cell plug CC2 may have a greater vertical thickness than the vertical structure VS.

As shown in FIG. 3, in the edge area EA, a third cell plug CC3 may be arranged between the bit line BL and the peripheral circuit line 122. For example, an upper surface of the third cell plug CC3 may contact the bottom surface of the bit line BL, and a bottom surface of the third cell plug CC3 may contact the upper surface of the uppermost peripheral circuit line 122_U. The third cell plug CC3 may electrically connect the bit line BL to the peripheral circuit transistor 120 through the peripheral circuit line 122.

In embodiments, the third cell plug CC3 may be arranged in a third cell plug hole CC3H penetrating the isolation insulating layer 128 and the buried insulating layer 134. The third cell plug hole CC3H may be formed through the process of removing a portion of the buried insulating layer 134 and a portion of the isolation insulating layer 128 from the upper surface of the buried insulating layer 134, and in embodiments, the third cell plug hole CC3H may have inclined sidewalls such that an upper width of the third cell plug hole CC3H is greater than a bottom width the third cell plug hole CC3H.

The third cell plug CC3 may include a first end portion CC3a (e.g., the first end portion CC3a in contact with the upper surface of the uppermost peripheral circuit line 122_U) arranged to be close to (i.e., adjacent) the peripheral circuit transistor 120 and a second end portion CC3b opposite to the first end portion CC3a. The width of the second end portion CC3b of the third cell plug CC3 may be greater than the width of the first end portion CC3a of the third cell plug CC3.

In embodiments, as the capacitor structure CAP is arranged between the bit line BL and the peripheral circuit transistor 120, the height of the third cell plug CC3 in the vertical direction Z may be greater than the height of the capacitor structure CAP in the vertical direction Z (e.g., the height of the vertical structure VS in the vertical direction Z).

An upper wire layer 162 and an upper via 164 may be arranged on an upper surface of the buried insulating layer 134, and an upper insulating layer 166 covering the upper wire layer 162 and the upper via 164 may be arranged.

As shown in FIG. 3, in the edge area EA, a peripheral plug PC1 may be arranged between the upper wire layer 162 and the peripheral circuit line 122. For example, an upper surface of the peripheral plug PC1 may contact the bottom surface of the upper wire layer 162, and a bottom surface of the peripheral plug PC1 may contact the upper surface of the uppermost peripheral circuit line 122_U. The peripheral plug PC1 may electrically connect the upper wire layer 162 to the peripheral circuit transistor 120 through the peripheral circuit line 122.

In embodiments, the peripheral plug PC1 may be arranged in a peripheral plug hole PC1H penetrating the isolation insulating layer 128 and the buried insulating layer 134. The peripheral plug hole PC1H may be formed through the process of removing a portion of the buried insulating layer 134 and a portion of the isolation insulating layer 128 from the upper surface of the buried insulating layer 134, and in embodiments, the peripheral plug hole PC1H may have inclined sidewalls such that an upper width of the peripheral plug hole PC1H is greater than a bottom width of the peripheral plug hole PC1H.

The peripheral plug PC1 may include a first end portion PC1a (e.g., the first end portion PC1a in contact with the upper surface of the uppermost peripheral circuit line 122_U) arranged to be close to (i.e., adjacent) the peripheral circuit transistor 120 and a second end portion PC1b opposite to the first end portion PC1a. The width of the second end portion PC1b of the peripheral plug PC1 may be greater than the width of the first end portion PC1a of the peripheral plug PC1.

In general, peripheral circuit structures and cell transistors are sequentially arranged on a substrate, and capacitor structures are arranged on the cell transistors. A plurality of openings with a relatively high aspect ratio are formed in a mold insulating layer, and lower electrodes are formed in the openings. However, leaning of the openings may occur during the process of etching the openings with a high aspect ratio, resulting in misalignment where an opening is not aligned on/with a corresponding landing pad but on/with another, adjacent landing pad.

According to embodiments, however, the openings 130H with bottom portions exposing the upper surface of the plate electrode PE may be formed by penetrating the capacitor mold insulating layer 130, and the vertical structures VS may be formed by sequentially forming the first electrodes 142, the capacitor dielectric layers 144, and the second electrode 146 in the openings 130H. Therefore, because the plate electrode PE is exposed at the bottom portions of the openings 130H, there is no need for the openings 130H to align with the landing pads, and thus, defects caused by the leaning of the openings 130H may be prevented.

In addition, in the etching process for forming the openings 130H with a relatively high aspect ratio, an electrical path to the substrate 110 may be provided to the plate electrode PE through the first cell plug CC1 connected to the bottom surface of the plate electrode PE, and electrical damage to the plate electrode PE such as arc discharge, which may occur due to collisions of plasma or ions used during the etching process, may be prevented from occurring. Therefore, the semiconductor device 100 may have excellent electrical performance.

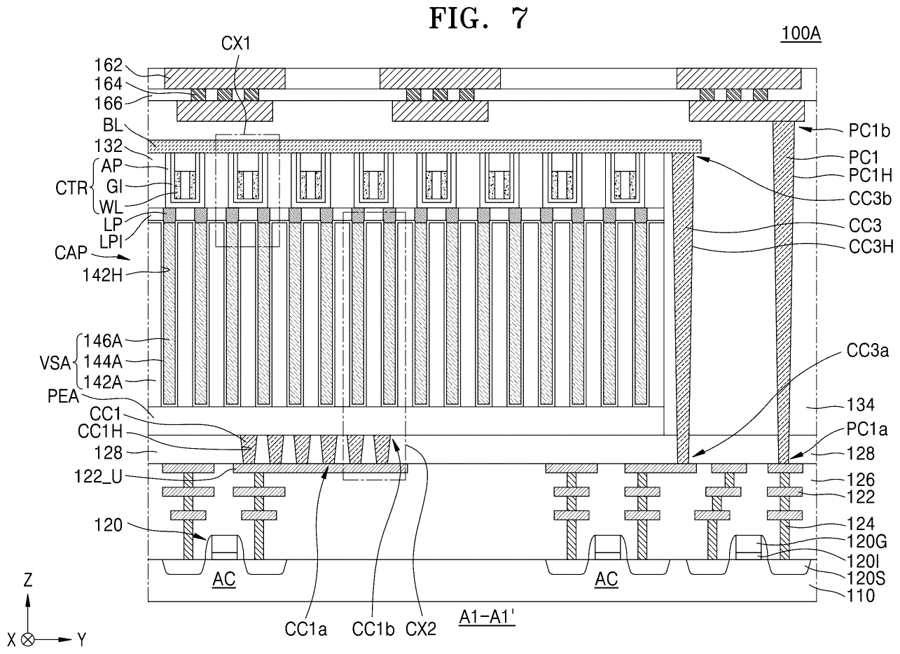

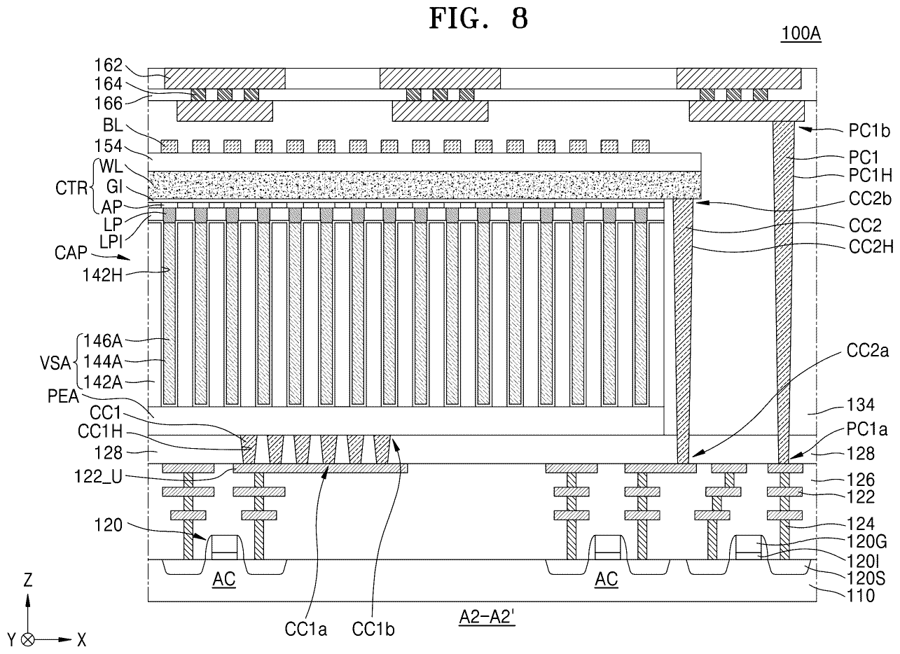

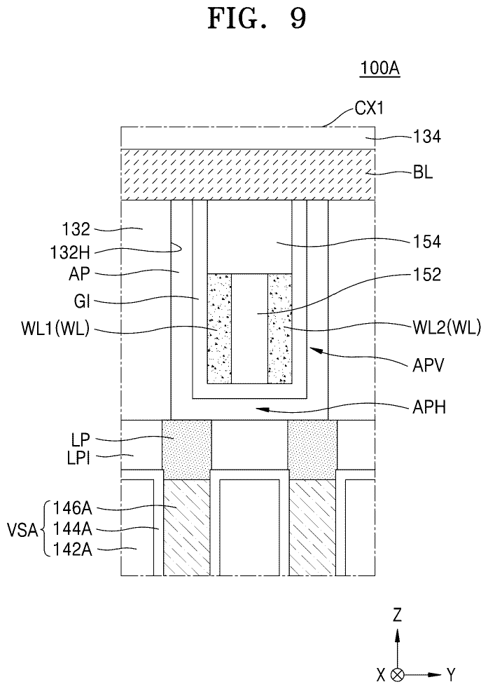

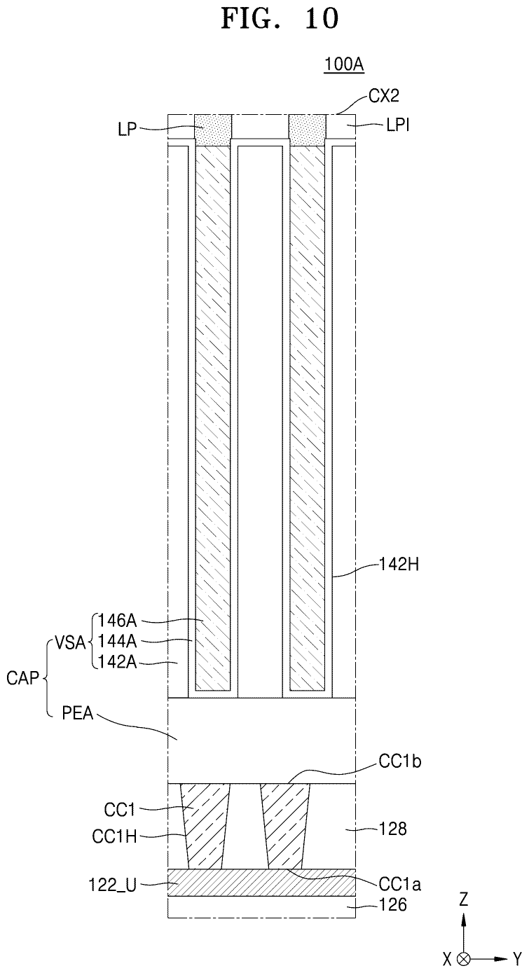

FIGS. 7 and 8 are cross-sectional views of a semiconductor device 100A according to embodiments. FIG. 9 is an enlarged view illustrating a region CX1 of FIG. 7. FIG. 10 is an enlarged view illustrating a region CX2 of FIG. 7.

Referring to FIGS. 7 to 10, a capacitor structure CAP may include a plate electrode PEA and a vertical structure VSA, and the vertical structure VSA may include a first electrode 142A including a plurality of openings 142H, a capacitor dielectric layer 144A arranged in the openings 142H of the first electrode 142A, and a plurality of second electrodes 146A arranged in the openings 142H of the first electrode 142A.

In embodiments, the plate electrode PEA and the first electrode 142A may be formed integrally with each other. For example, the plate electrode PEA may include the same material as the first electrode 142A. In embodiments, the plate electrode PEA and the first electrode 142A may include Si, SiGe, W, WN, Ti, TiN, and a combination thereof.

In embodiments, the first electrode 142A may have a relatively great height, and an etching process for forming the plurality of openings 142H with a relatively high aspect ratio in the first electrode 142A may be performed. In this case, the openings 142H may be formed at a depth not to completely penetrate the first electrode 142A, and a portion of the first electrode 142A located at a lower vertical level than the openings 142H may be referred to as the plate electrode PEA.

In embodiments, the capacitor dielectric layer 144A may be conformally arranged on the inner wall of the openings 142H and also arranged on the upper surface of the first electrode 142A. The second electrode 146A may be arranged on the capacitor dielectric layer 144A inside each opening 142H.

In embodiments, in the etching process for forming the openings 142H with a relatively high aspect ratio, an electrical path to the substrate 110 may be provided to the plate electrode PEA through the first cell plug CC1 connected to the bottom surface of the plate electrode PEA, and electrical damage to the plate electrode PEA such as arc discharge, which may occur due to collisions of plasma or ions used during the etching process, may be prevented from occurring. Therefore, the semiconductor device 100A may have excellent electrical performance.

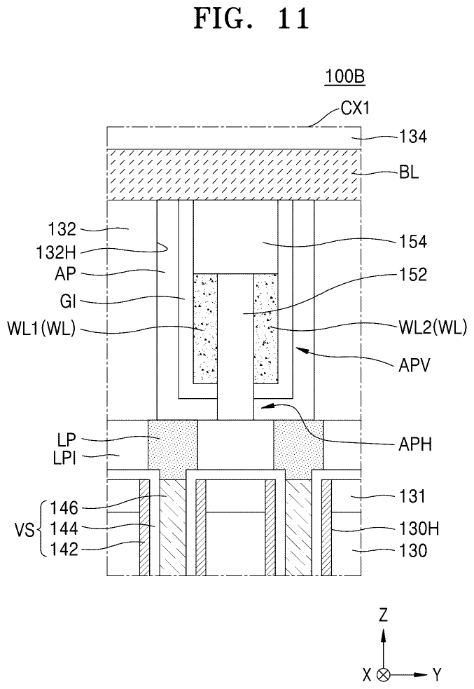

FIG. 11 is a cross-sectional view of a semiconductor device 100B according to embodiments.

Referring to FIG. 11, in each opening 132H of the channel mold insulating layer 132, two active semiconductor layers AP may be spaced apart from each other in the second horizontal direction Y. The two active semiconductor layers AP may each have an L-shaped vertical cross-section and may have a mirror symmetry structure with respect to each other; for example, the active semiconductor layer AP arranged on the first sidewall of each opening 132H may be spaced apart from the active semiconductor layer AP arranged on the second sidewall of each opening 132H, and a first buried insulating layer 152 may be arranged between one active semiconductor layer AP and the other active semiconductor layer AP.

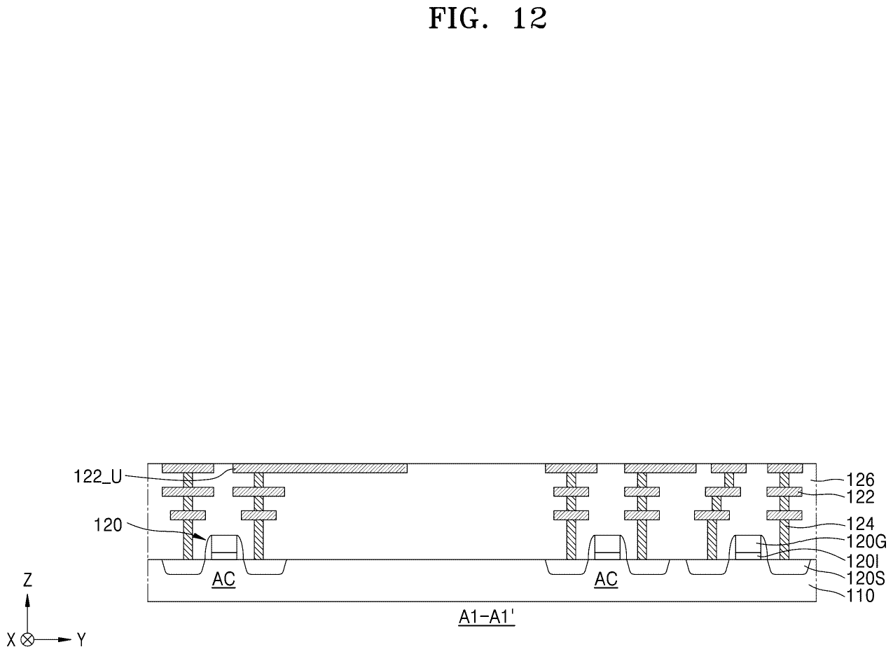

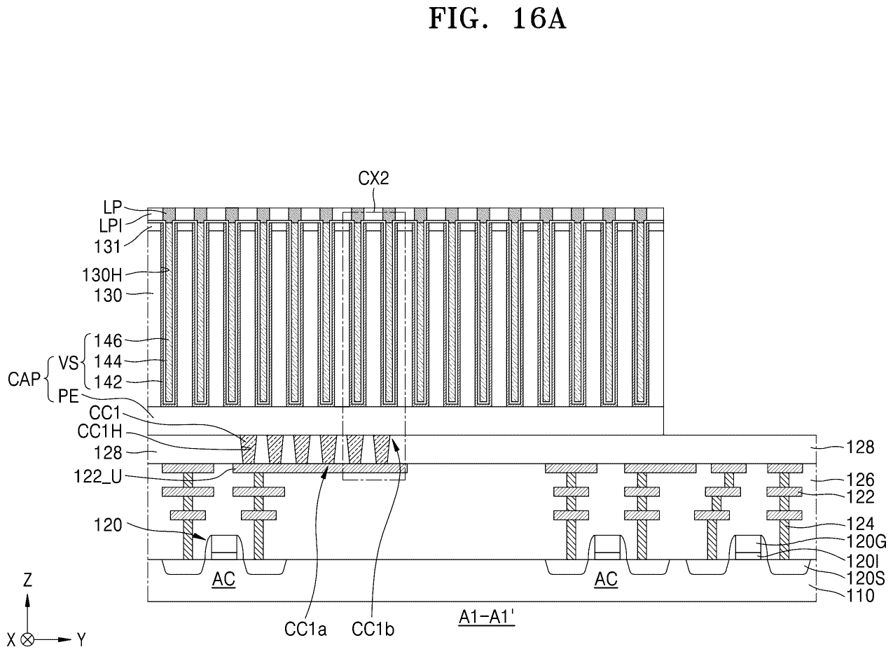

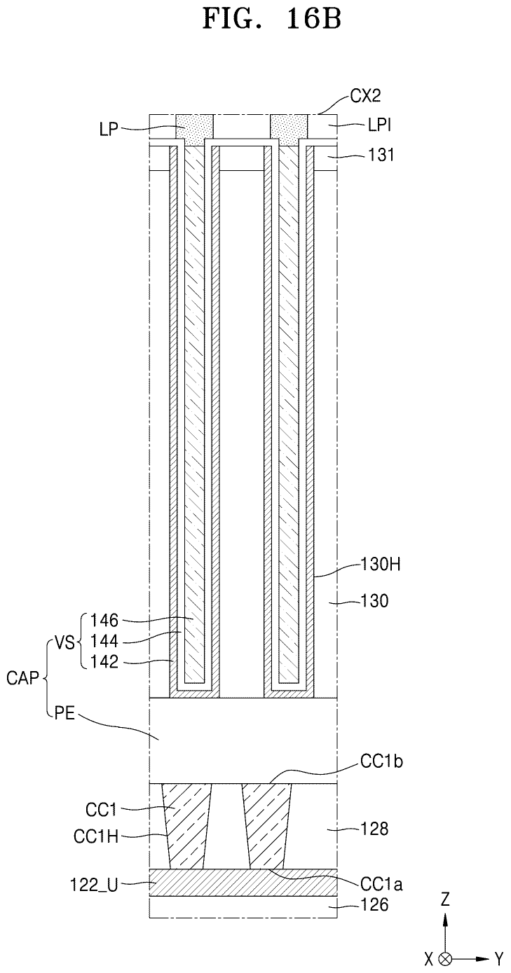

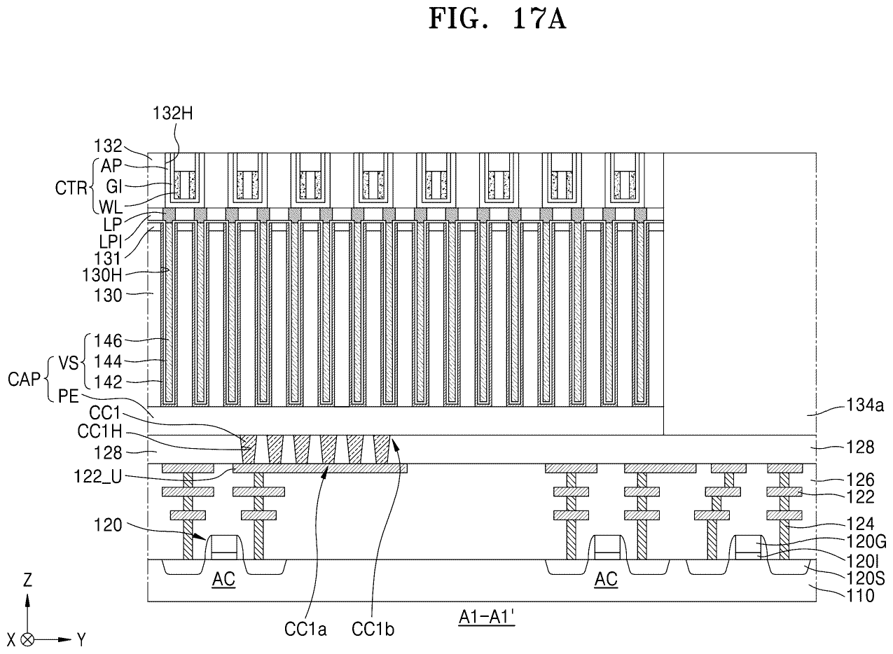

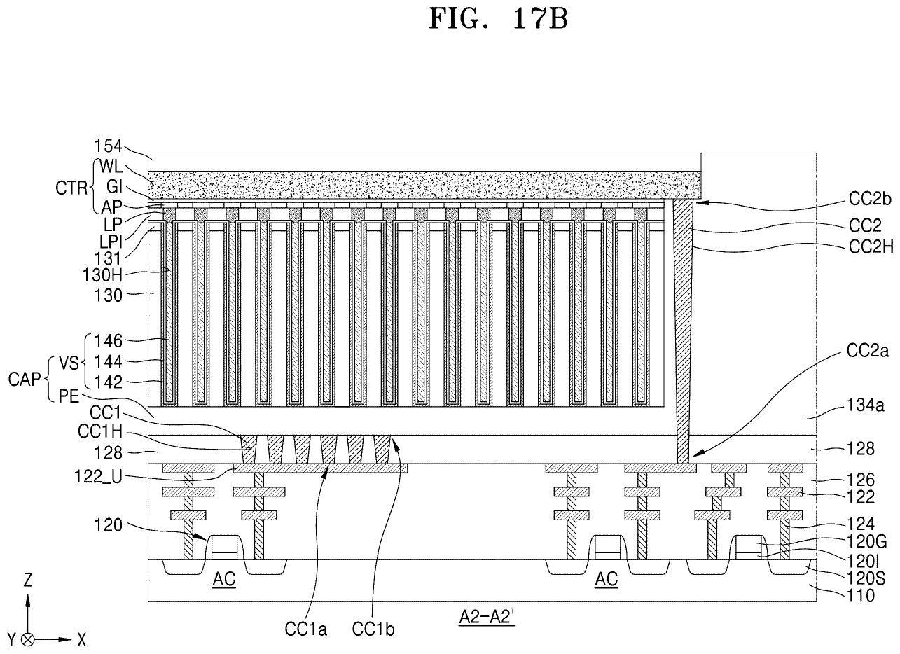

FIGS. 12 to 15, 16A, 16B, 17A, 17B, 18, 19A, 19B, 20A, 20B, 21A, and 21B schematically show a method of manufacturing the semiconductor device 100, according to embodiments. FIGS. 12 to 15, 16A, 17A, 18, 19A, 20A, and 20B respectively are cross-sectional views of the semiconductor device taken along a line A1-A1 of FIG. 2, FIG. 16B is an enlarged view illustrating a region CX2 of FIG. 16A, and FIGS. 17B, 19B, 20B, and 21B respectively are cross-sectional views of the semiconductor device taken along a line A2-A2 of FIG. 2.

Referring to FIG. 12, the active area AC may be formed on the substrate 110, and the peripheral circuit transistor 120 may be formed in the active area AC. For example, the peripheral circuit transistor 120 may include a gate electrode 120G, a gate insulating layer 120I, and a source/drain area 120S.

Then, the peripheral circuit line 122 and the peripheral circuit contact 124 electrically connected to the substrate 110 and the peripheral circuit transistor 120 may be formed, and the peripheral circuit insulating layer 126 covering the peripheral circuit line 122 and the peripheral circuit contact 124 may be formed on the substrate 110. The peripheral circuit insulating layer 126 may be formed using an oxide layer, a nitride layer, a low-k dielectric layer, or a combination thereof.

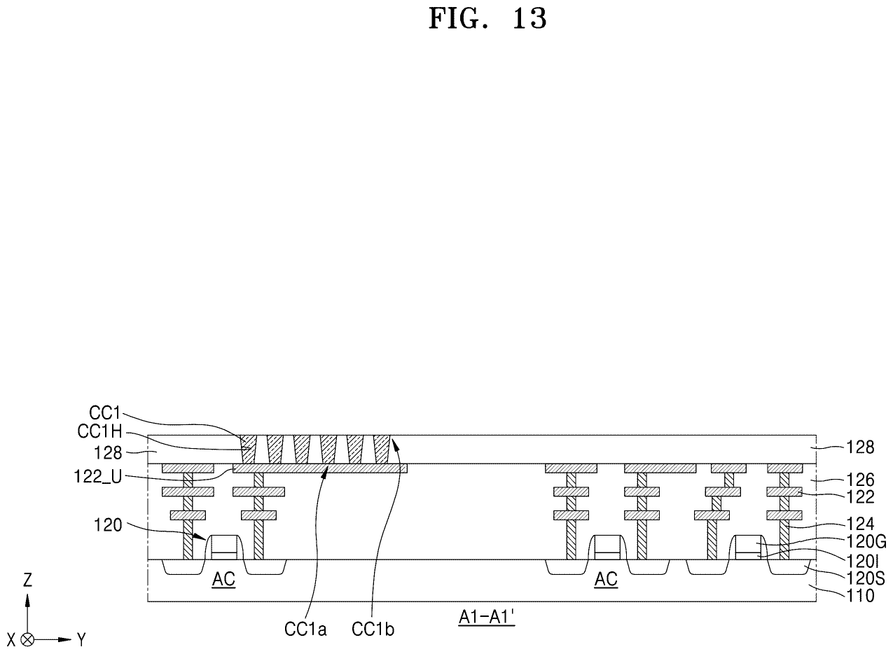

Referring to FIG. 13, the isolation insulating layer 128 may be formed on the peripheral circuit insulating layer 126. The isolation insulating layer 128 may be formed using an oxide layer, a nitride layer, a low-k dielectric layer, or a combination thereof.

A mask pattern may be formed on the isolation insulating layer 128, and a portion of the isolation insulating layer 128 may be removed by using the mask pattern as an etch mask, thereby forming the first cell plug hole CC1H. The first cell plug hole CC1H may penetrate the isolation insulating layer 128, and the uppermost peripheral circuit line 122_U may be exposed at the bottom portion of the first cell plug hole CC1H.

In embodiments, during the process of removing a portion of the isolation insulating layer 128, the upper portion of the first cell plug hole CC1H may be exposed to the etching atmosphere for a longer period, and for example, the first cell plug hole CC1H may have the inclined sidewalls such that the upper width of the first cell plug hole CC1H is greater than the bottom width of the first cell plug hole CC1H.

Then, the first cell plug CC1 may be formed by filling the interior of the first cell plug hole CC1H with a conductive material. The bottom surface of the first cell plug CC1 may be in contact with the uppermost peripheral circuit line 122_U.

In embodiments, the first cell plug CC1 may include the first end portion CC1a arranged to be close to the peripheral circuit transistor 120, and the second end portion CC1b opposite to the first end portion CC1a. The width of the second end portion CC1b of the first cell plug CC1 may be greater than the width of the first end portion CC1a of the first cell plug CC1.

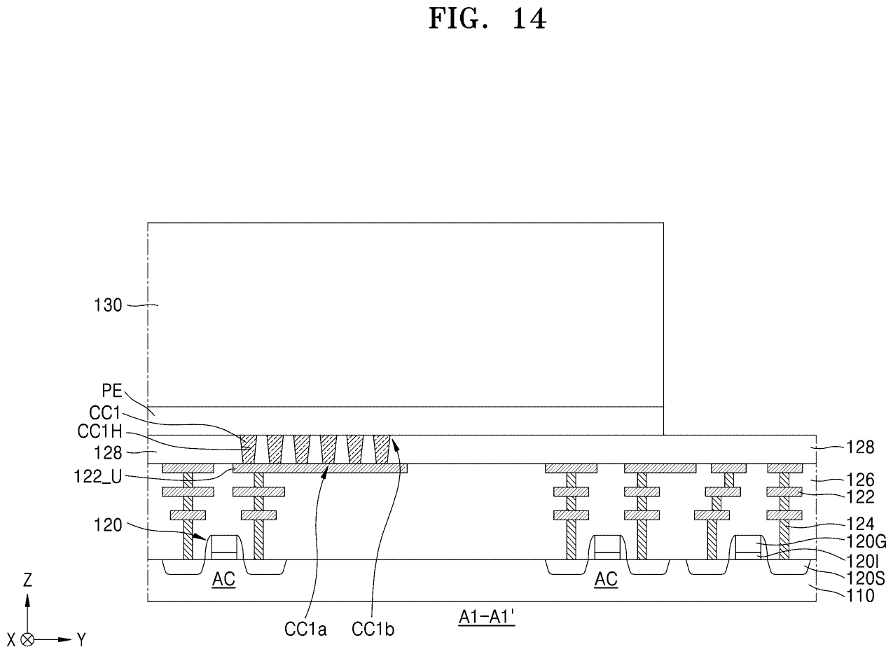

Referring to FIG. 14, the plate electrode PE may be formed on the isolation insulating layer 128 and the first cell plug CC1. In embodiments, the plate electrode PE may include Si, SiGe, W, WN, Ti, TiN, and a combination thereof.

Then, the capacitor mold insulating layer 130 may be formed on the plate electrode PE. In embodiments, the capacitor mold insulating layer 130 may be formed using silicon oxide, silicon nitride, silicon oxynitride, or a combination thereof. In embodiments, the capacitor mold insulating layer 130 may have a stack structure including at least two mold layers and a support layer arranged between the at least two mold layers. The capacitor mold insulating layer 130 may have a relatively greater height.

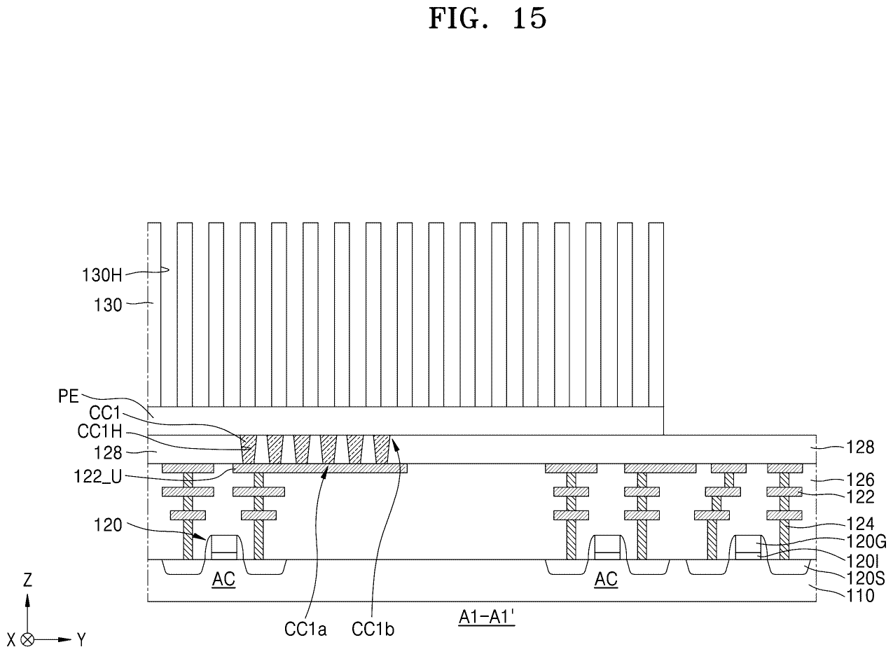

Referring to FIG. 15, a mask pattern may be formed on the capacitor mold insulating layer 130, and a portion of the capacitor mold insulating layer 130 may be removed by using the mask pattern as an etch mask, thereby forming a plurality of openings 130H.

The openings 130H may penetrate the capacitor mold insulating layer 130 and may be formed to the depth at which the upper surface of the plate electrode PE is exposed. The openings 130H may have a relatively high aspect ratio. In embodiments, the process of forming the openings 130H may include any one of a plasma etching process, a reactive ion etching process, and a dry etching process.

In embodiments, in the etching process for forming the openings 130H, an electrical path to the substrate 110 may be provided to the plate electrode PE through the first cell plug CC1 connected to the plate electrode PE, and electrical damage to the plate electrode PE such as arc discharge, which may occur due to collisions of plasma or ions used during the etching process, may be prevented from occurring.

In addition, in a semiconductor device according to the comparative example, a plurality of openings need to be aligned with landing pads, and in this case, defects, for example, connections or communications between openings and adjacent landing pads, may occur because of the leaning of the openings. Therefore, the difficulty of the process of aligning the openings with the landing pads corresponding thereto may be high. However, in embodiments, despite the leaning of the openings 130H during the etching process for forming the openings 130H, the upper surface of the plate electrode PE may be exposed at the bottom portions of the openings 130H, and thus, the difficulty of the etching process may be reduced.

Referring to FIGS. 16A and 16B, the vertical structure VS may be formed in the openings 130H.

In embodiments, the vertical structure VS may be formed by sequentially forming the first electrode 142, the capacitor dielectric layer 144, and the second electrode 146 in the openings 130H.

In embodiments, the etch stop layer 131 may be additionally formed on the capacitor mold insulating layer 130, the first electrode 142 may be formed on the inner wall of the openings 130H and the upper surface of the capacitor mold insulating layer 130, and a portion of the first electrode 142 (e.g., a portion of the first electrode 142 arranged on the upper surface of the capacitor mold insulating layer 130) may be removed through a planarization process until the upper surface of the etch stop layer 131 is exposed. Accordingly, the first electrode 142 may have a cylindrical shape with a closed bottom, and the bottom surface of the first electrode 142 may contact the upper surface of the plate electrode PE.

Then, the landing pads LP may be formed on the vertical structures VS, respectively. For example, a conductive layer may be formed on the capacitor mold insulating layer 130 to be connected to the second electrodes 146, and the conductive layer may be patterned to form landing pads LP respectively placed on the second electrodes 146.

Then, the landing pad isolation insulating layer LPI surrounding the sidewalls of the landing pads LP may be formed on the capacitor mold insulating layer 130.

Referring to FIGS. 17A and 17B, the cell transistors CTR may be formed on the landing pads LP, respectively.

In embodiments, the channel mold insulating layer 132 may be formed on the landing pads LP and the landing pad isolation insulating layer LPI, and then a portion of the channel mold insulating layer 132 may be removed, thereby forming a plurality of mold openings 132H extending in the first horizontal direction X.

In each of the mold openings 132H, the cell transistor CTR including the active semiconductor layer AP, the gate insulating layer GI, and the word line WL may be formed. In embodiments, the active semiconductor layer AP may have a U-shaped vertical cross-section and may include the horizontal extension APH (FIG. 5) contacting the landing pad LP and the vertical extension APV (FIG. 5) contacting the channel mold insulating layer 132. The gate insulating layer GI may be arranged on the upper surface of the horizontal extension APH and the sidewall of the vertical extension APV of the active semiconductor layer AP. The word line WL may face the vertical extension APV of the active semiconductor layer AP with the gate insulating layer GI therebetween.

In embodiments, a buried insulating layer 134a may be formed on the isolation insulating layer 128 to cover the sidewalls of the plate electrode PE and the channel mold insulating layer 132. The buried insulating layer 134a is a single layer, but according to necessity or design preference, the buried insulating layer 134a may have a stack structure including insulating layers.

In embodiments, before the process of forming the word line WL, a portion of the buried insulating layer 134a and a portion of the isolation insulating layer 128 may be removed to form the second cell plug hole CC2H, and the second cell plug CC2 filling the second cell plug hole CC2H may be formed.

For example, an upper surface of the second cell plug CC2 may contact the bottom surface of the word line WL, and a bottom surface of the second cell plug CC2 may contact the upper surface of the uppermost peripheral circuit line 122_U. The second cell plug CC2 may electrically connect the word line WL to the peripheral circuit transistor 120 through the peripheral circuit line 122.

In embodiments, during the process of removing a portion of the buried insulating layer 134a, the upper portion of the second cell plug hole CC2H may be exposed to the etching atmosphere for a longer period, and for example, the second cell plug hole CC2H may have the inclined sidewalls such that the upper width of the second cell plug hole CC2H is greater than the bottom width of the second cell plug hole CC2H.

The second cell plug CC2 may include the first end portion CC2a arranged to be close to the peripheral circuit transistor 120 and the second end portion CC2b opposite to the first end portion CC2a. The width of the second end portion CC2b of the second cell plug CC2 may be greater than the width of the first end portion CC2a of the second cell plug CC2.

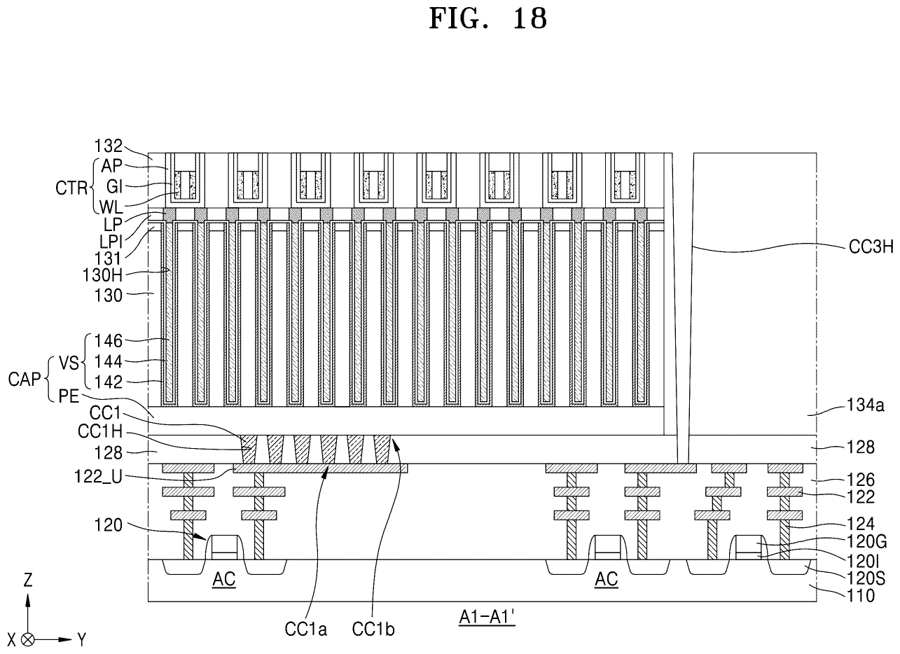

Referring to FIG. 18, a portion of the buried insulating layer 134a and a portion of the isolation insulating layer 128 may be removed to form the third cell plug hole CC3H.

In embodiments, during the process of removing a portion of the buried insulating layer 134a, the upper portion of the third cell plug hole CC3H may be exposed to the etching atmosphere for a longer period, and for example, the third cell plug hole CC3H may have the inclined sidewalls such that the upper width of the third cell plug hole CC3H is greater than the bottom width of the third cell plug hole CC3H.

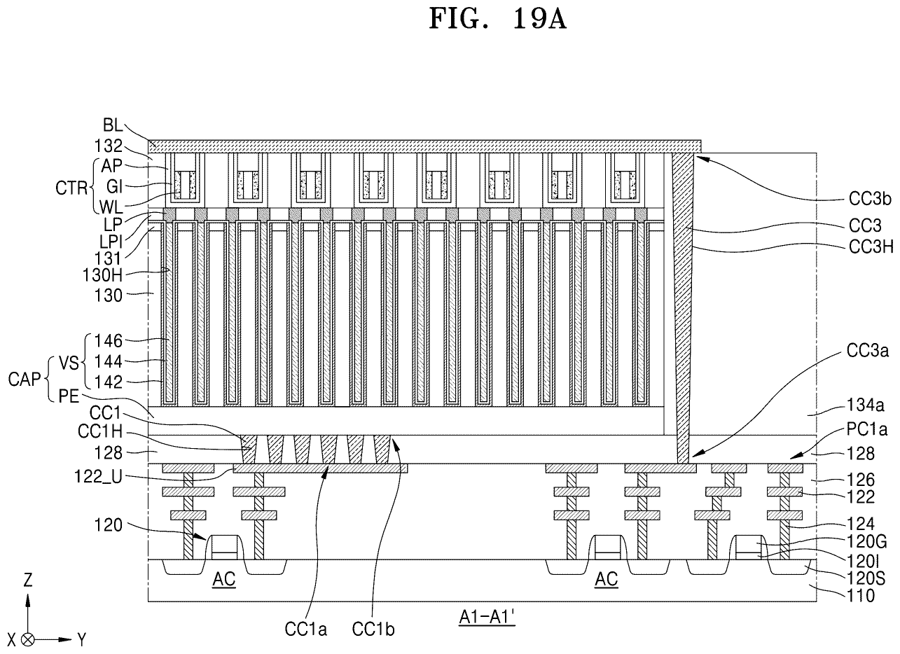

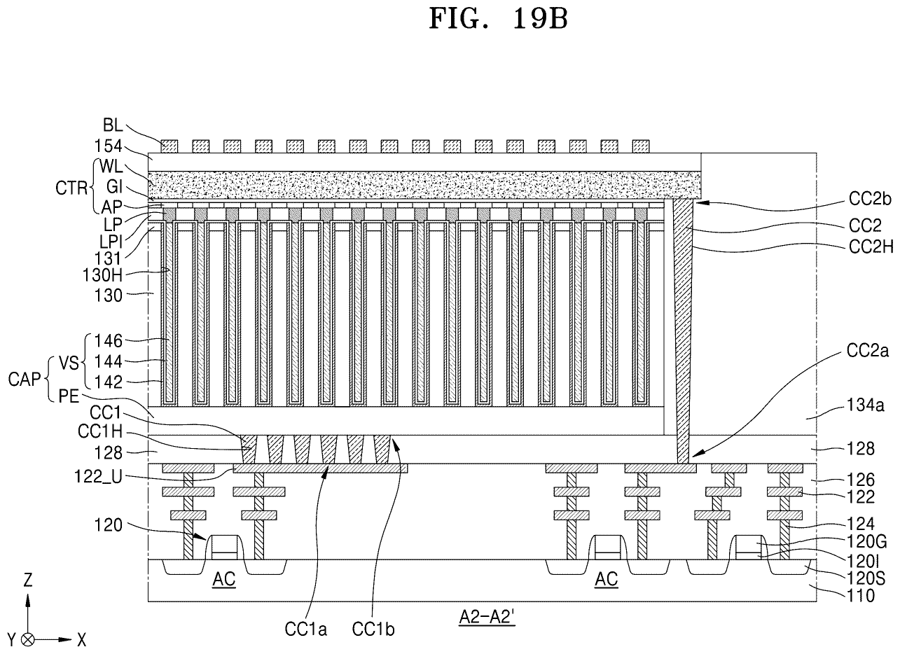

Referring to FIGS. 19A and 19B, the third cell plug CC3 filling the third cell plug hole CC3H may be formed.

The third cell plug CC3 may include the first end portion CC3a arranged to be close to the peripheral circuit transistor 120 and the second end portion CC3b opposite to the first end portion CC3a. The width of the second end portion CC3b of the third cell plug CC3 may be greater than the width of the first end portion CC3a of the third cell plug CC3.

Then, the bit line BL may be formed on the cell transistor CTR. In an edge portion of a memory cell array, the bit line BL may be electrically connected to the third cell plug CC3, and for example, the upper surface of the third cell plug CC3 may contact the bottom surface of the bit line BL. The third cell plug CC3 may electrically connect the bit line BL to the peripheral circuit transistor 120 through the peripheral circuit line 122.

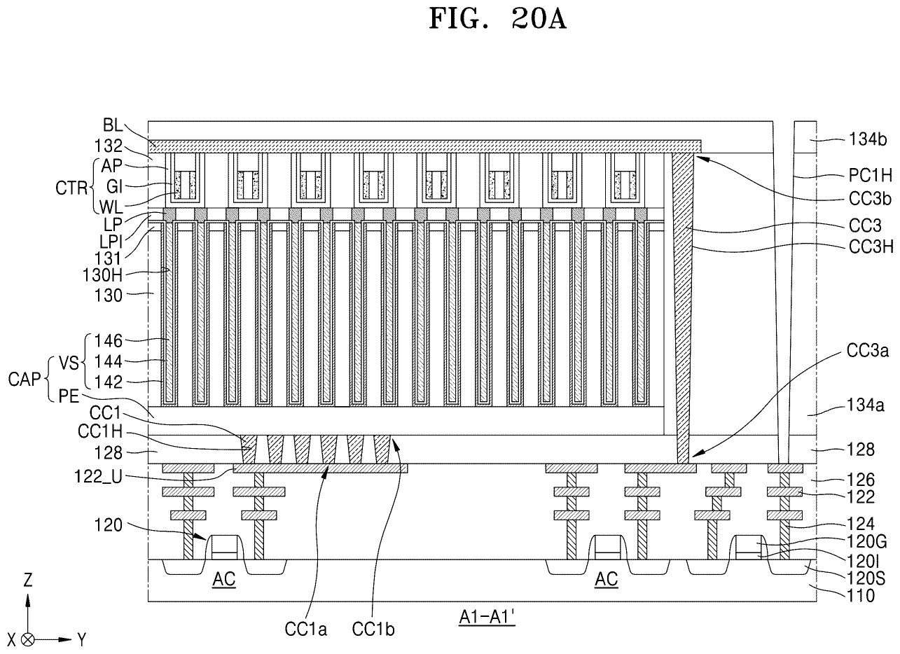

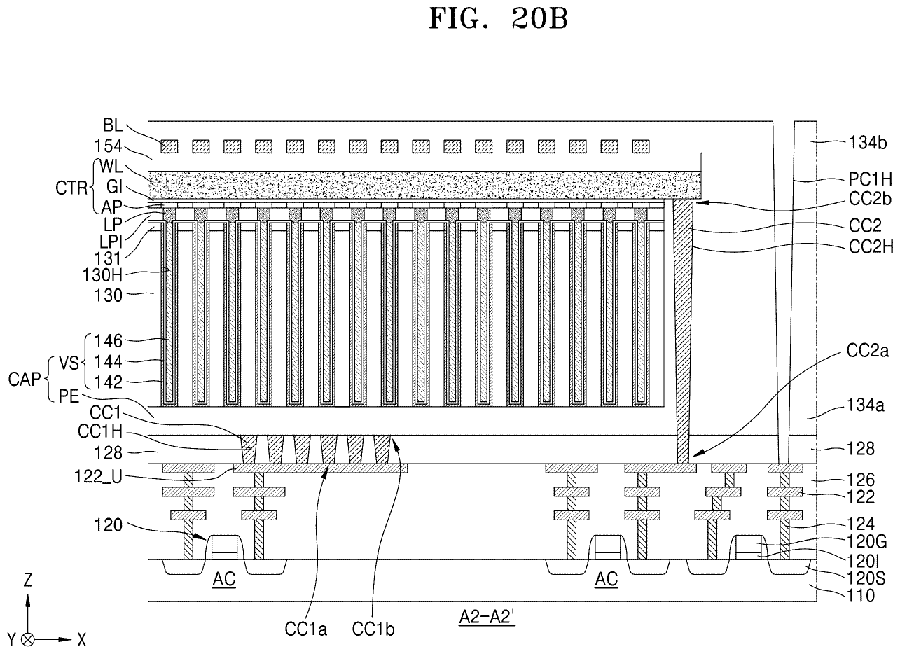

Referring to FIGS. 20A and 20B, the buried insulating layer 134b covering the bit line BL may be formed on the buried insulating layer 134a, and a portion of the buried insulating layer 134a, a portion of the buried insulating layer 134b, and a portion of the isolation insulating layer 128 may be removed, thereby forming the peripheral plug hole PC1H.

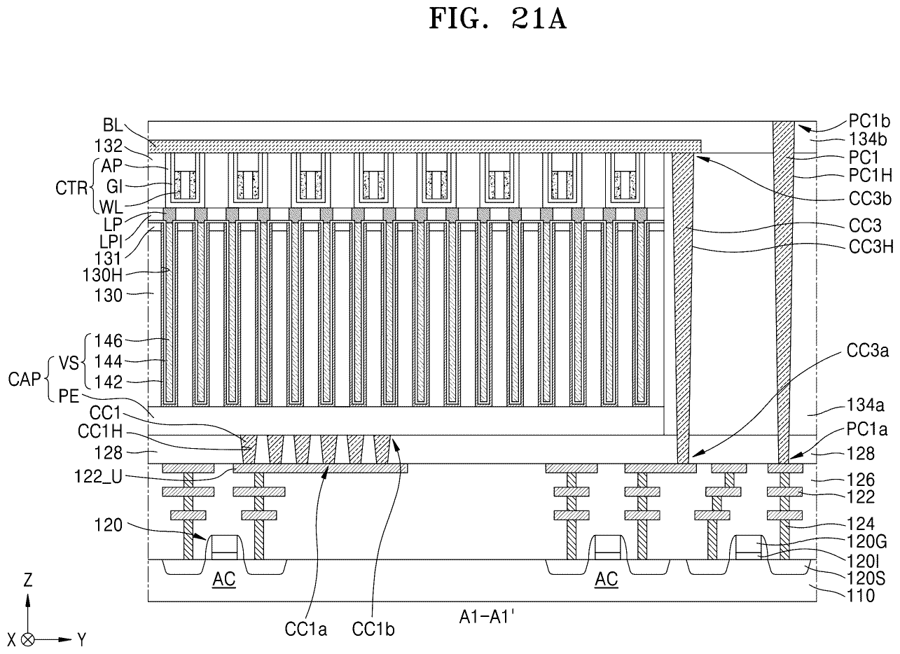

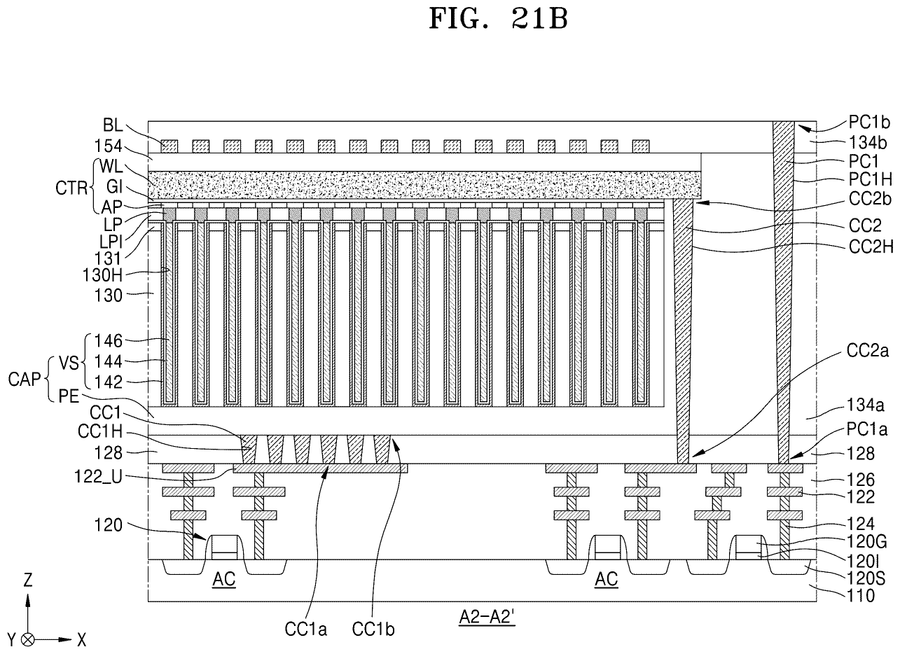

Then, referring to FIGS. 21A and 21B, the peripheral plug PC1 filling the peripheral plug hole PC1H may be formed.

The peripheral plug PC1 may electrically connect the upper wire layer 162 (FIG. 3) to the peripheral circuit transistor 120 through the peripheral circuit line 122.

Referring back to FIGS. 3 and 4, the upper wire layer 162 and the upper via 164 may be formed on the buried insulating layer 134b, and the upper insulating layer 166 covering the upper wire layer 162 and the upper via 164 may be formed.

The semiconductor device 100 may be completed through the above-described processes.

According to embodiments, in the etching process for forming the openings 130H with a relatively high aspect ratio, the plate electrode PE may be exposed at the bottom portions of the openings 130H, and thus, the difficulty of the process of forming the openings 130H may be reduced.

Also, in the etching process, an electrical path to the substrate 110 may be provided to the plate electrode PE through the first cell plug CCI connected to the bottom surface of the plate electrode PE, and electrical damage to the plate electrode PE such as arc discharge, which may occur due to collisions of plasma or ions used during the etching process, may be prevented from occurring. Therefore, the semiconductor device 100 may have excellent electrical performance.

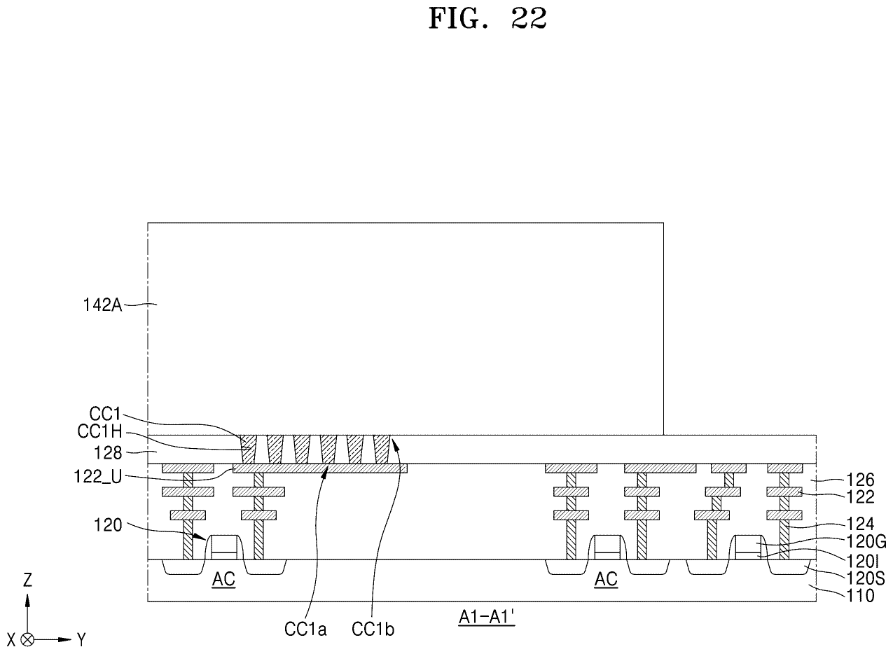

FIGS. 22, 23, 24A, 24B, 25A, and 25B schematically show a method of manufacturing the semiconductor device 100A, according to embodiments.

The peripheral circuit transistor 120 and the first cell plug CC1 may be formed on the substrate 110 by performing the process described above with reference to FIGS. 12 and 13.

Referring to FIG. 22, the first electrode 142A may be formed on the first cell plug CC1 and the isolation insulating layer 128. The first electrode 142A may include Si, SiGe, W, WN, Ti, TiN, and a combination thereof.

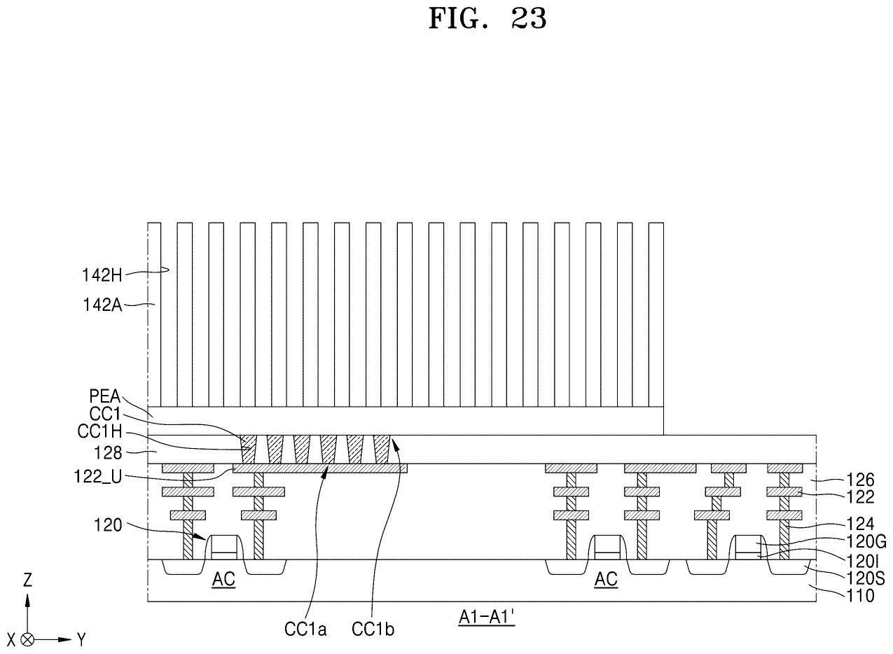

Referring to FIG. 23, a mask pattern may be formed on the first electrode 142A, and a portion of the first electrode 142A may be removed by using the mask pattern as an etch mask, thereby forming the openings 142H.

The openings 142H may have a relatively high aspect ratio. In embodiments, the process of forming the openings 142H may include any one of the plasma etching process, the reactive ion etching process, and the dry etching process.

The openings 142H may be formed to a depth not to completely penetrate the first electrode 142A, and a portion of the first electrode 142A located at a lower vertical level than the openings 142H may serve (and be referred to) as the plate electrode PEA.

In embodiments, in the process of forming the openings 142H, an electrical path to the substrate 110 may be provided through the first cell plug CC1 connected to the first electrode 142A, and electrical damage to the first electrode 142A such as arc discharge, which may occur due to collisions of plasma or ions used during the etching process, may be prevented from occurring.

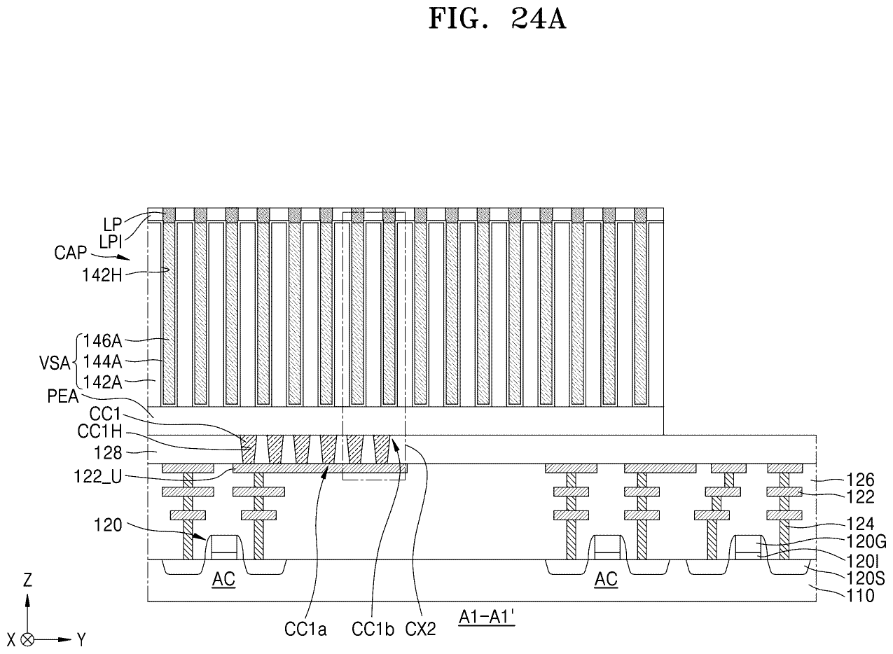

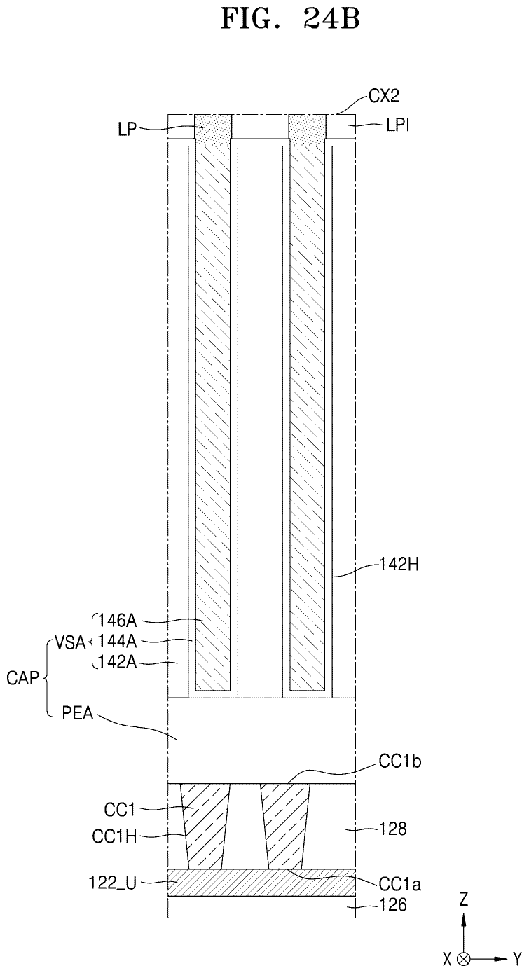

Referring to FIGS. 24A and 24B, the capacitor dielectric layer 144A may be formed on the inner walls of the openings 142H. The capacitor dielectric layer 144A may be conformally arranged on the inner walls of the openings 142H to a thickness at which the interiors of the openings 142H are not completely filled. The capacitor dielectric layer 144A may also be arranged on the upper surface of the first electrode 142A.

Then, the second electrodes 146A may be respectively formed in the openings 142H. The second electrode 146A may be formed in a pillar shape to fill the interiors of the openings 142H.

Then, the landing pads LP may be formed on the second electrodes 146A, and the landing pad isolation insulating layer LPI surrounding the sidewalls of the landing pads LP may be formed.

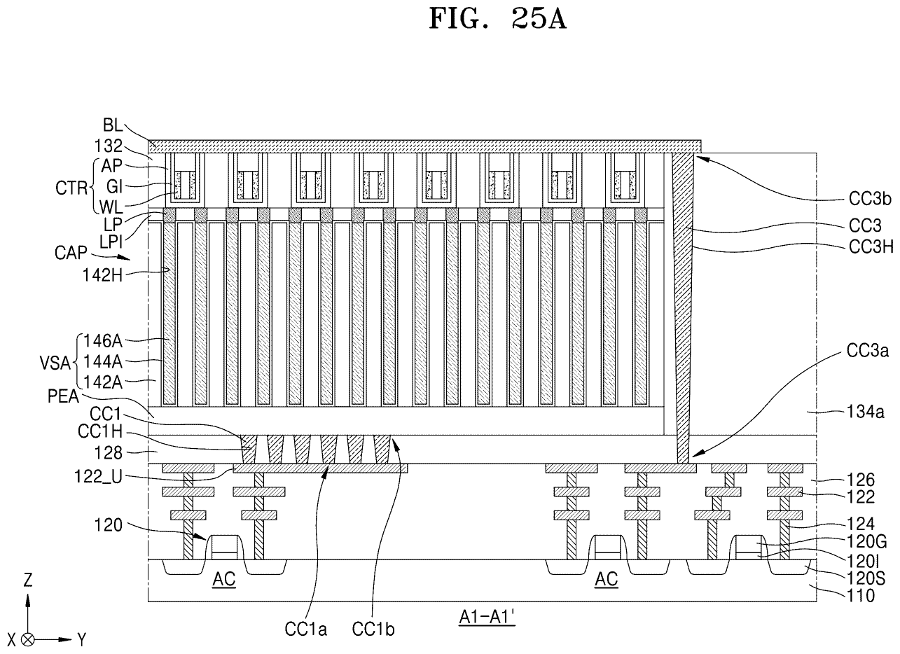

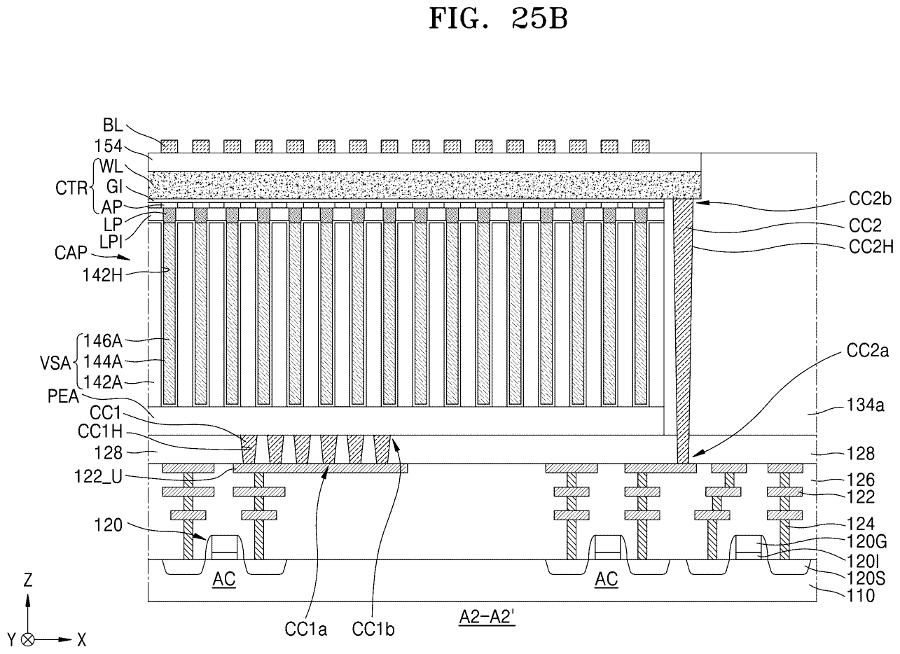

Referring to FIGS. 25A and 25B, the cell transistor CTR may be formed on the landing pads LP, and the buried insulating layer 134a covering the vertical structure VSA may be formed. Moreover, the bit line BL may be formed on the cell transistor CTR. In addition, by removing a portion of the buried insulating layer 134a, the second cell plug CC2 connected to the word line WL may be formed, and the third cell plug CC3 connected to the bit line BL may be formed.

Referring back to FIGS. 7 and 8, the semiconductor device 100A may be completed by forming the peripheral plug PC1, the upper wire layer 162, the upper via 164, and the upper insulating layer 166.

According to an embodiment, in the etching process of forming openings with a relatively high aspect ratio, as a plate electrode is exposed at the bottom portions of the openings, the difficulty in the process of forming the openings may increase. In addition, during the etching process, an electrical path to a substrate may be provided to a plate electrode through a first cell plug connected to the bottom surface of the plate electrode, and electrical damage to the plate electrode such as arc discharge, which may occur due to collisions of plasma or ions used during the etching process, may be prevented from occurring. Therefore, a semiconductor device may have excellent electrical performance.

While the inventive concept has been particularly shown and described with reference to embodiments thereof, it will be understood that various changes in form and details may be made therein without departing from the scope of the following claims.

What is claimed is:

1. A semiconductor device comprising:
a peripheral circuit on a substrate;
a capacitor structure on the peripheral circuit and comprising a plate electrode and a vertical structure extending on the plate electrode in a vertical direction perpendicular to an upper surface of the substrate, wherein the vertical structure comprises a first electrode, a second electrode, and a capacitor dielectric layer between the first electrode and the second electrode;
a cell transistor at a higher vertical level than the capacitor structure and electrically connected to the capacitor structure;
a first cell plug between, in the vertical direction, the plate electrode and the peripheral circuit and adjacent and electrically connected to a bottom surface of the plate electrode; and
a second cell plug between, in the vertical direction, the cell transistor and the peripheral circuit,
wherein the first cell plug comprises a first end portion adjacent the peripheral circuit and a second end portion opposite to the first end portion, and
wherein a width of the second end portion of the first cell plug is greater than a width of the first end portion of the first cell plug.

2. The semiconductor device of claim 1,
wherein an upper surface of the second end portion of the first cell plug is in contact with the bottom surface of the plate electrode,
wherein the second cell plug comprises a first end portion adjacent the peripheral circuit and a second end portion opposite to the first end portion of the second cell plug, and
wherein a width of the second end portion of the second cell plug is greater than a width of the first end portion of the second cell plug.

3. The semiconductor device of claim 1, wherein the cell transistor comprises:
an active semiconductor layer at a higher vertical level than the capacitor structure, extending in the vertical direction, and comprising a first end portion and a second end portion, wherein the first end portion of the active semiconductor layer is adjacent and electrically connected to the second electrode; and
a word line on a sidewall of the active semiconductor layer, and
the second cell plug is electrically connected to the word line.

4. The semiconductor device of claim 3,
wherein the active semiconductor layer comprises a vertical portion extending in the vertical direction and a horizontal portion connected to the vertical portion and extending in a horizontal direction,
wherein the horizontal portion comprises the first end portion of the active semiconductor layer,
wherein an upper portion of the vertical portion comprises the second end portion of the active semiconductor layer, and
wherein the semiconductor device further comprises a landing pad between a bottom surface of the horizontal portion and the second electrode.

5. The semiconductor device of claim 3, further comprising:
a bit line on the second end portion of the active semiconductor layer; and
a third cell plug extending between the bit line and the peripheral circuit in the vertical direction and electrically connecting the bit line to the peripheral circuit,
wherein the third cell plug comprises a first end portion adjacent the peripheral circuit and a second end portion opposite to the first end portion of the third cell plug, and
wherein a width of the second end portion of the third cell plug is greater than a width of the first end portion of the third cell plug.

6. The semiconductor device of claim 1, further comprising:
a wire layer at a higher vertical level than the cell transistor; and
a peripheral plug extending between the wire layer and the peripheral circuit in the vertical direction and electrically connecting the wire layer to the peripheral circuit,
wherein the peripheral plug comprises a first end portion adjacent the peripheral circuit and a second end portion opposite to the first end portion of the peripheral plug, and
wherein a width of the second end portion of the peripheral plug is greater than a width of the first end portion of the peripheral plug.

7. The semiconductor device of claim 1, further comprising a mold insulating layer on the plate electrode and comprising a plurality of openings extending in the vertical direction,
wherein the vertical structure is in each of the plurality of openings.

8. The semiconductor device of claim 7,
wherein the first electrode is on an inner wall of each of the plurality of openings and is in contact with the mold insulating layer,
wherein the capacitor dielectric layer is on an inner sidewall of the first electrode and an upper surface of the mold insulating layer in each of the plurality of openings, and
wherein the second electrode is in an interior of each of the plurality of openings.

9. The semiconductor device of claim 7,
wherein the cell transistor comprises an active semiconductor layer at a higher vertical level than the capacitor structure, extending in the vertical direction, and comprising a first end portion and a second end portion,
wherein the first end portion of the active semiconductor layer is adjacent and electrically connected to the second electrode, and
wherein the active semiconductor layer comprises at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), and zirconium zinc tin oxide (ZrₓZn_{y}Sn_{z}O).

10. The semiconductor device of claim 1, wherein a height of the second cell plug in the vertical direction is greater than the height of the vertical structure in the vertical direction.

11. A semiconductor device comprising:
a peripheral circuit on a substrate;
a capacitor structure on the peripheral circuit and comprising a plate electrode and a plurality of vertical structures extending on the plate electrode in a vertical direction perpendicular to an upper surface of the substrate, wherein each of the plurality of vertical structures comprises a first electrode, a second electrode, and a capacitor dielectric layer between the first electrode and the second electrode;
a mold insulating layer on the plate electrode and comprising a plurality of openings extending in the vertical direction, wherein the plurality of vertical structures are in the plurality of openings, respectively;
an active semiconductor layer on the mold insulating layer and electrically connected to the second electrode;
a word line on a sidewall of the active semiconductor layer;
a bit line on an upper surface of the active semiconductor layer;
a first cell plug between the plate electrode and the peripheral circuit in the vertical direction and adjacent and electrically connected to a bottom surface of the plate electrode; and
a second cell plug extending between the word line and the peripheral circuit in the vertical direction and electrically connecting the word line to the peripheral circuit.

12. The semiconductor device of claim 11,
wherein the first cell plug comprises a first end portion adjacent the peripheral circuit and a second end portion opposite to the first end portion, and
wherein a width of the second end portion of the first cell plug is greater than a width of the first end portion of the first cell plug.

13. The semiconductor device of claim 11,
wherein the second cell plug comprises a first end portion adjacent the peripheral circuit and a second end portion opposite to the first end portion, and
wherein a width of the second end portion of the second cell plug is greater than a width of the first end portion of the second cell plug.

14. The semiconductor device of claim 11, further comprising a third cell plug extending between the bit line and the peripheral circuit in the vertical direction and electrically connecting the bit line to the peripheral circuit,
wherein the third cell plug comprises a first end portion adjacent the peripheral circuit and a second end portion opposite to the first end portion, and
wherein a width of the second end portion of the third cell plug is greater than a width of the first end portion of the third cell plug.

15. The semiconductor device of claim 11,
wherein the active semiconductor layer comprises a vertical portion extending in the vertical direction and a horizontal portion connected to the vertical portion and extending in a horizontal direction,
wherein the semiconductor device further comprises a landing pad between a bottom surface of the horizontal portion and the second electrode.

16. The semiconductor device of claim 15,
wherein the second electrode extends in the vertical direction in each of the plurality of openings of the mold insulating layer,
wherein the capacitor dielectric layer surrounds a sidewall of the second electrode in each of the plurality of openings of the mold insulating layer,
wherein the first electrode surrounds a sidewall of the capacitor dielectric layer in each of the plurality of openings of the mold insulating layer,
wherein a bottom surface of the first electrode is in contact with an upper surface of the plate electrode, and
wherein an upper surface of the second electrode is in contact with a bottom surface of the landing pad.

17. The semiconductor device of claim 16,
wherein the first electrode has a ring-shaped horizontal cross-section, and
wherein the second electrode has a circular horizontal cross-section.

18. A semiconductor device comprising:
a peripheral circuit on a substrate;
a capacitor structure on the peripheral circuit and comprising a plate electrode and a plurality of vertical structures extending on the plate electrode in a vertical direction perpendicular to an upper surface of the substrate, wherein each of the plurality of vertical structures comprises a first electrode electrically connected to the plate electrode and extending in the vertical direction, a second electrode on a sidewall of the first electrode, and a capacitor dielectric layer between the first electrode and the second electrode;
a mold insulating layer on the plate electrode and surrounding sidewalls of the plurality of vertical structures;
an active semiconductor layer at a higher vertical level than the capacitor structure, extending in the vertical direction, and comprising a first end portion and a second end portion, wherein the first end portion is adjacent and electrically connected to the second electrode;
a word line on a sidewall of the active semiconductor layer;
a bit line adjacent and electrically connected to the second end portion of the active semiconductor layer;
a wire layer at a higher vertical level than the bit line;
a first cell plug between the plate electrode and the peripheral circuit in the vertical direction and adjacent and electrically connected to a bottom surface of the plate electrode;
a second cell plug extending between the word line and the peripheral circuit in the vertical direction and electrically connecting the word line to the peripheral circuit;
a third cell plug extending between the bit line and the peripheral circuit in the vertical direction and electrically connecting the bit line to the peripheral circuit; and
a peripheral plug extending between the wire layer and the peripheral circuit in the vertical direction and electrically connecting the wire layer to the peripheral circuit.

19. The semiconductor device of claim 18,
wherein the first cell plug comprises a first end portion adjacent the peripheral circuit and a second end portion opposite to the first end portion of the first cell plug,
wherein a width of the second end portion of the first cell plug is greater than a width of the first end portion of the first cell plug,
wherein the peripheral plug comprises a first end portion adjacent the peripheral circuit and a second end portion opposite to the first end portion of the peripheral plug, and
wherein a width of the second end portion of the peripheral plug is greater than a width of the first end portion of the peripheral plug.

20. The semiconductor device of claim 18,
wherein the second cell plug comprises a first end portion adjacent the peripheral circuit and a second end portion opposite to the first end portion of the second cell plug,
wherein a width of the second end portion of the second cell plug is greater than a width of the first end portion of the second cell plug,
wherein the third cell plug comprises a first end portion adjacent the peripheral circuit and a second end portion opposite to the first end portion of the third cell plug, and
wherein a width of the second end portion of the third cell plug is greater than a width of the first end portion of the third cell plug.
